(19) United States
(12) Patent Application Publication
(10) Pub. No.: US 2013/0175614 A1
(43) Pub. Date: Jul. 11, 2013

(54) SEMICONDUCTOR DEVICES AND METHODS OF FABRICATING THE SAME

(71) Applicant: KYOUNG IL NA, Daejeon (KR)

(72) Inventor: KYOUNG IL NA, Daejeon (KR)

(73) Assignee: Electronics and Telecommunications Research Institute, Daejeon (KR)

(21) Appl. No.: 13/609,120

(22) Filed: Sep. 10, 2012

(30) Foreign Application Priority Data
Jan. 9, 2012 (KR) 10-2012-0002583

(51) Int. Cl. H01L 27/06; H01L 21/8238

(52) U.S. Cl. 257/338; 438/207; 257/E27.015; 257/E21.642

(57) ABSTRACT

Semiconductor devices and methods of fabricating the same are provided. The semiconductor device includes a substrate having a first region including a first element and a second region including a second element and including a lower substrate and an upper substrate bonded to each other, an epitaxial layer and an insulating layer disposed between the lower substrate and the upper substrate, the epitaxial layer disposed in the first region, and the insulating layer disposed in the second region, a device isolation pattern separating the first element from the second element, and a doped pattern disposed between the upper substrate and the insulating layer and between the upper substrate and the epitaxial layer. The first element is electrically connected to the lower substrate through the doped pattern and the epitaxial layer. The second element is electrically insulated from the lower substrate by the doped pattern and the insulating layer.

### CROSS-REFERENCE TO RELATED APPLICATIONS

This U.S. non-provisional patent application claims priority under 35 U.S.C. §119 to Korean Patent Application No. 10-2012-0002583, filed on Jan. 9, 2012, the entirety of which is incorporated by reference herein.

### BACKGROUND

The inventive concept relates to semiconductor devices and, more particularly, to A bipolar-CMOS-DMOS (BCD) devices for a smart power integrated circuit and methods of fabricating the same.

Semiconductor devices may be components determining quality in various electronic equipments including home appliances. The semiconductor devices having improved reliability and other characteristics have been increasingly demanded with the tendency for high capacity, multi-function and/or same size of the electronic equipments. Various techniques improving characteristics of the semiconductor devices have been introduced for satisfying the above demands.

Recently, smart power integrated circuits are attractive in the electronic equipments. The smart power integrated circuit may integrate functions of various power devices one chip. The smart power integrated circuits may be mainly used in high frequency and high voltage-resistance info-communication systems such as an automotive power integrated circuit and a DC/DC converter. A conventional bipolar-CMOS-DMOS (BCD) type power integrated circuit may generally use a VDMOS device. However, the VDMOS may have a great on-resistance and a driving capability of the VDMOS may be deteriorated.

### SUMMARY

Embodiments of the inventive concept may provide semiconductor devices including a power control element, a signal control element, and a current control element, and methods of fabricating the same.

Embodiments of the inventive concept may also provide semiconductor devices having high reliability and methods of fabricating the same.

In one aspect, a semiconductor device may include: a substrate having a first region including a first element and a second region including a second element, the substrate including a lower substrate and an upper substrate bonded to each other; an epitaxial layer and an insulating layer disposed between the lower substrate and the upper substrate, the epitaxial layer disposed in the first region, and the insulating layer disposed in the second region; a device isolation pattern separating the first element from the second element; and a doped pattern disposed between the upper substrate and the insulating layer and between the upper substrate and the epitaxial layer. The first element may be electrically connected to the lower substrate through the doped pattern and the epitaxial layer. The second element may be electrically insulated from the lower substrate by the doped pattern and the insulating layer.

In some embodiments, the doped pattern may include a lower doped layer parallel to the lower substrate; and a sidewall doped layer vertically extending from the lower doped layer. The sidewall doped layer may be in contact with the device isolation pattern.

In other embodiments, the semiconductor device may further include: a buried doped layer disposed in the lower substrate. The buried doped layer may be in contact with the epitaxial layer in the first region. The upper and lower substrates may be doped with dopants of a first conductivity type; and the epitaxial layer and the doped pattern may be doped with dopants of a second conductivity type different from the first conductivity type.

In still other embodiments, the first element may include a deep well disposed to be in contact with the doped pattern. The first element may be a DMOS transistor. The first element may include a source, a drain, and a trench type gate; and the source, the drain, and the trench type gate may be connected to metal interconnections disposed on a top surface of the upper substrate.

In yet other embodiments, the second element may include at least one well spaced apart from the doped pattern. The second element may be a CMOS element. The substrate may further include a third region including a third element, and the third element may be a bipolar transistor.

In another aspect, a method of fabricating a semiconductor substrate may include: forming an insulating layer on a lower substrate having first to third regions; forming an epitaxial layer on the lower substrate of the first region; forming a lower doped layer on an upper substrate having first to third regions; bonding the upper substrate to the lower substrate to bring the epitaxial layer and the insulating layer into contact with the lower doped layer; forming a deep well in the upper substrate of the first region; forming at least one well in the upper substrate of the second region; forming trenches penetrating the upper substrate and the lower doped layer; forming side wall layers on sidewalls of the trenches, respectively; and forming device isolation patterns filling the trenches, respectively.

In some embodiments, forming the epitaxial layer may include: patterning the insulating layer to expose the lower substrate in the first region; and performing a selective epitaxial growth process to form the epitaxial layer.

In other embodiments, the lower doped layer may be formed by an ion implantation process and a diffusion process; and the lower doped layer may be doped with dopants of a conductivity type different from that of the upper substrate. The deep well of the first region may be formed to be in contact with the lower doped layer.

In still other embodiments, the method may further include: thermally treating the upper substrate to diffuse dopants in the epitaxial layer into the lower substrate under the epitaxial layer, thereby forming a buried doped layer in the lower substrate.

In yet other embodiments, the method may further include: forming a deep well in the upper substrate of the second region and/or the third region. The deep well of the second region and/or the third region and the deep well of the first region may be formed simultaneously. The at least one well of the second region may be formed to be spaced apart from the lower doped layer.

In yet still embodiments, forming the sidewall doped layers may include: depositing a spacer insulating layer including dopants of a high concentration on the sidewalls of the trenches; and thermally treating the spacer insulating layer.

In yet still embodiments, forming the device isolation patterns may include: depositing a device isolation insulating layer filling the trenches in which the sidewall doped layers are formed; and planarizing the device isolation insulating layer until a top surface of the upper substrate is exposed.

In yet still embodiments, the method may further include: forming a DMOS element in the first region; forming a CMOS element in the second region; and forming a bipolar element in the third region.

### BRIEF DESCRIPTION OF THE DRAWINGS

The inventive concept will become more apparent in view of the attached drawings and accompanying detailed description.

FIGS. 1 to 18 are cross-sectional views illustrating a method of fabricating a semiconductor device according to some embodiments of the inventive concept;

FIG. 19 is a cross-sectional view illustrating a semiconductor device according to some embodiments of the inventive concept; and

FIGS. 20 to 24 are cross-sectional views illustrating a method of fabricating a semiconductor device according to other embodiments of the inventive concept.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

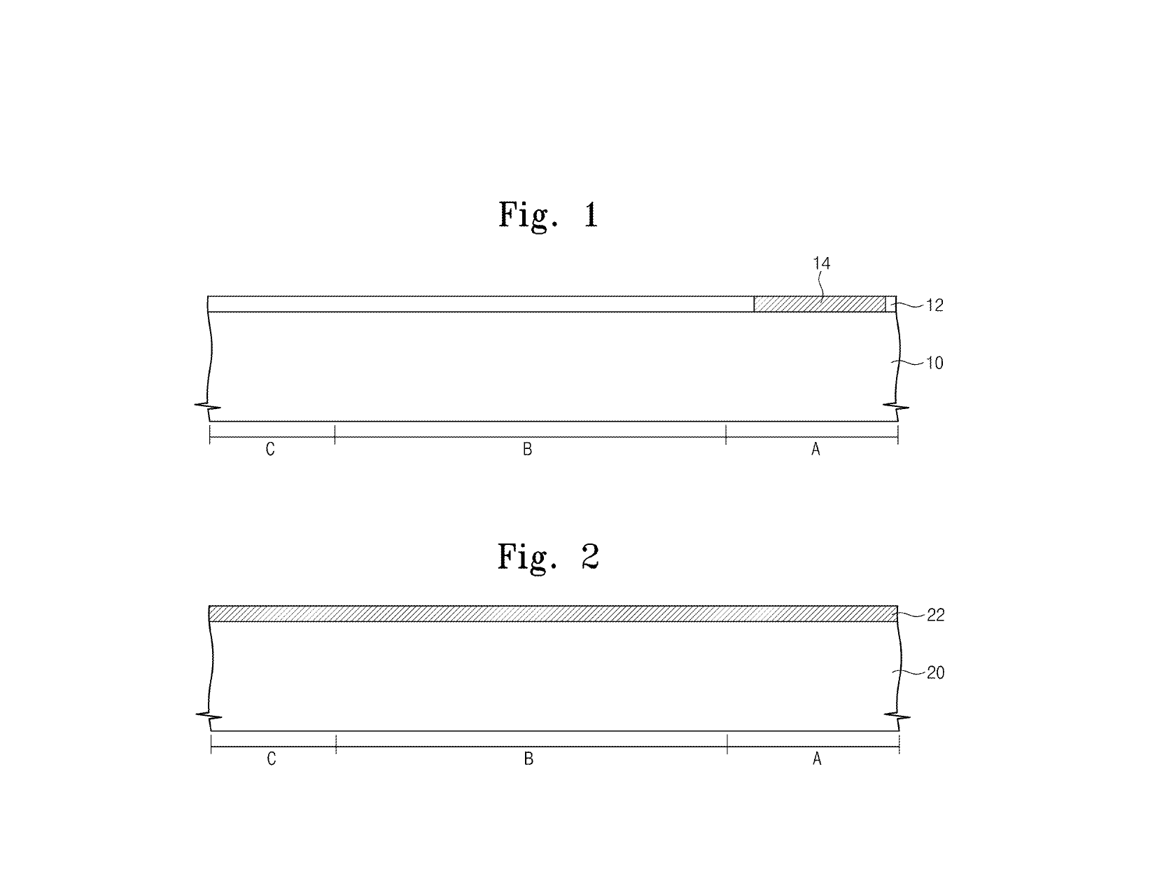

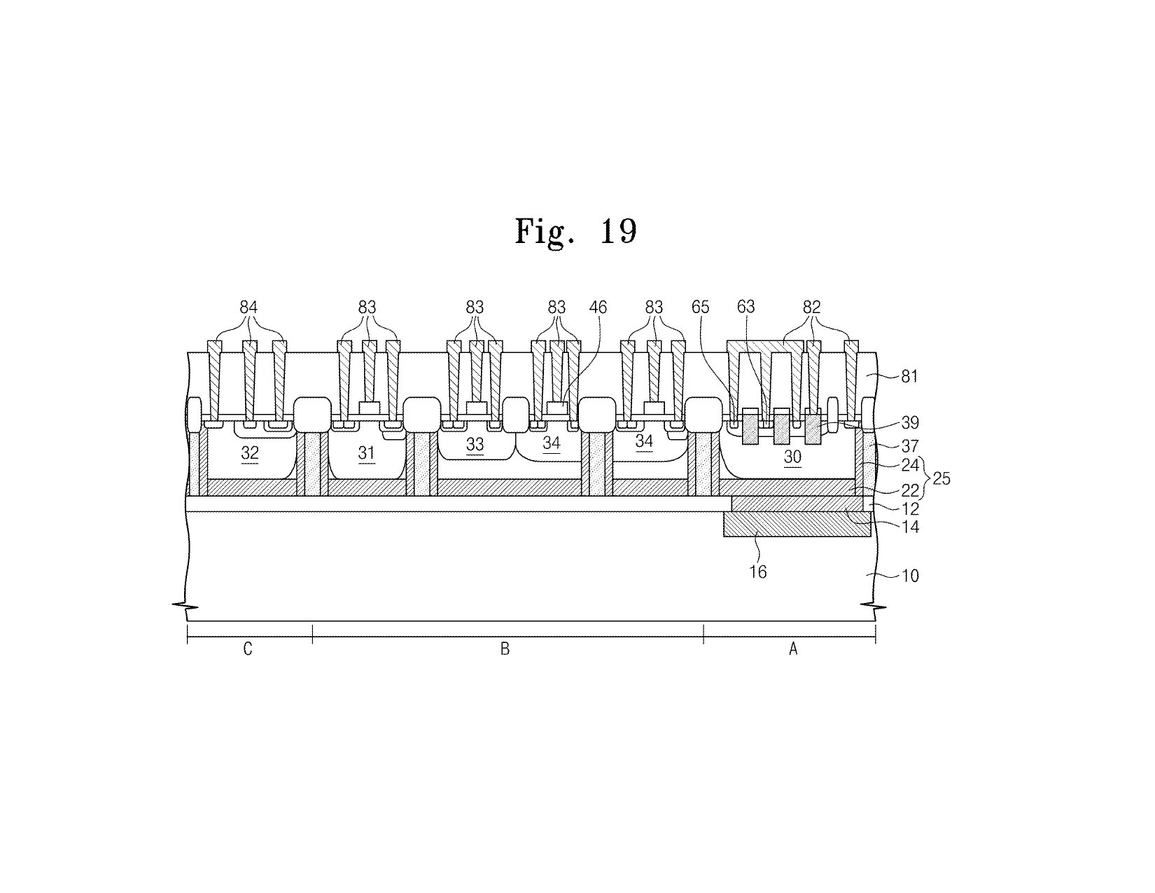

FIGS. 1 to 18 are cross-sectional views illustrating a method of fabricating a semiconductor device according to some embodiments of the inventive concept. FIG. 19 is a cross-sectional view illustrating a semiconductor device according to some embodiments of the inventive concept.

Referring to FIG. 1, a lower substrate 10 may be provided. The lower substrate 10 may include a first region A, a second region B, and a third region C. For example, the lower substrate 10 may be a silicon substrate or a germanium substrate. However, the inventive concept is not limited thereto. The lower substrate 10 may be one of the semiconductor substrates including other semiconductor materials. The lower substrate 10 may be a substrate doped with dopants. For example, the lower substrate 10 may be a p-type substrate. Elements different from each other may be formed in the first to third regions A, B, and C, respectively.

An epitaxial layer 14 may be formed on the lower substrate 10. In some embodiments, the epitaxial layer 14 may be formed on the lower substrate 10 in the first region A. Forming the epitaxial layer 14 may include forming an insulating layer 12 on the lower substrate 10 and defining a region in which the epitaxial layer 14 will be formed. Subsequently, the insulating layer 12 in the defined region may be etched, and then an epitaxial process may be performed to form the epitaxial layer 14. The epitaxial process may be performed using a source gas that includes at least one of Si, Ge, SiGe, AlP, AlAs, AlSb, GaN, GaP, GaAs, InP, InAs, InSb, ZnS, ZnSe, ZnTe, CdS, CdSe, CdTe, SiC, SiGe, C, and any compound thereof.

The epitaxial layer 14 may be doped by an in-situ method. The epitaxial layer 14 may be doped with dopants of a conductivity type different from that of the lower substrate 10 and have a high dopant concentration. For example, the epitaxial layer 14 may be doped with n⁺-type dopants.

Referring to FIG. 2, an upper substrate 20 including first to third regions A, B, and C. may be provided. The upper substrate 20 may be a silicon substrate or a germanium substrate. However, the inventive concept is not limited thereto. The upper substrate 20 may be one of the semiconductor substrates including other semiconductor materials. The upper substrate 20 may be a substrate doped with dopants. For example, the upper substrate 20 may be a p-type substrate.

A lower doped layer 22 may be formed on the upper substrate 20. The lower doped layer 22 may be formed by an ion implantation process and a diffusion process. The lower doped layer 22 may be doped with dopants of a conductivity type different from that of the upper substrate 20 and have a high dopant concentration. For example, the lower doped layer 22 may be doped with n₊-type dopants. The lower doped layer 22 may be formed on an entire top surface of the upper substrate 20.

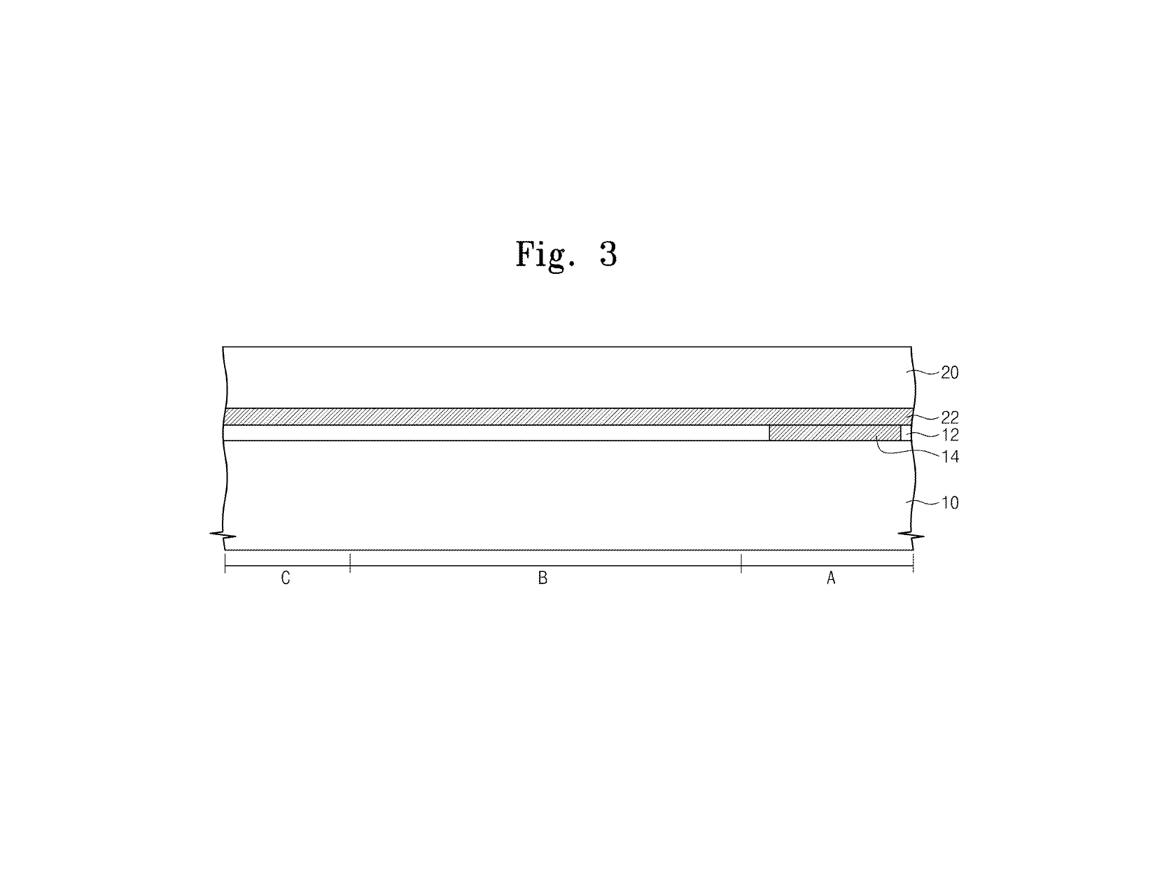

Referring to FIG. 3, the lower substrate 10 and the upper substrate 20 may be bonded to each other. Bonding the lower and upper substrates 10 and 20 may include cleaning the lower and upper substrates 10 and 20. Additionally, bonding the lower and upper substrates 10 and 20 may include overturning the upper substrate 20 and bonding the lower substrate 10 and the upper substrate 20 to bring the lower doped layer 22 of the upper substrate 20 into contact with the insulating layer 12 and the epitaxial layer 14 of the lower substrate. Subsequently, a thermal treatment process may be performed on the bonded lower and upper substrates 10 and 20. Next, a lapping process, a mirror polishing process, and a cleaning process may further be performed on a top surface (i.e., a surface opposite to the surface on which the lower doped layer 22 is formed) of the upper substrate 20 of the bonded structure.

Thus, the lower and upper substrates 10 and 20 may be bonded to each other in the state that the insulating layer 12 and the epitaxial layer 14 of the lower substrate 10 are in contact with the lower doped layer 22 of the upper substrate 20.

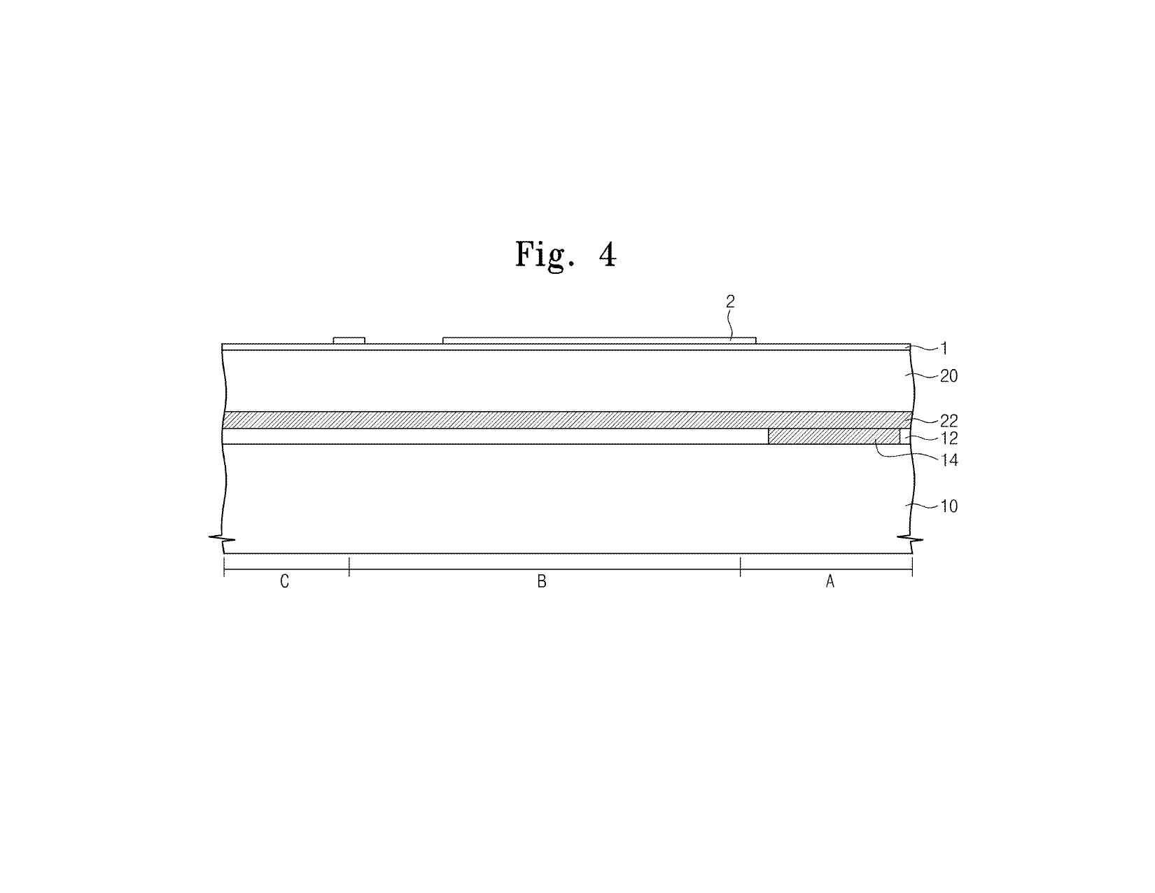

Referring to FIG. 4, an oxide layer 1 and a nitride layer 2 may be formed on the upper substrate 20 for forming deep wells. The oxide layer 1 and the nitride layer 2 may be formed by deposition processes. For example, the oxide layer 1 may be formed of a silicon oxide (SiO₂) layer and the nitride layer 2 may be formed of a silicon nitride (SiN) layer.

The nitride layer 2 may be patterned to define active regions in the upper substrate 20. Portions of the oxide layer 1 disposed on the active regions may be exposed by the patterning of the nitride layer 2. The active region may be disposed in at least one of the first to third regions A, B, and C. In some embodiments, the active regions may be disposed in the first to third regions A, B, and C, respectively. Meanwhile, the oxide layer 1 may be patterned with the nitride layer 2, such that the upper substrate 20 of the active regions may be exposed.

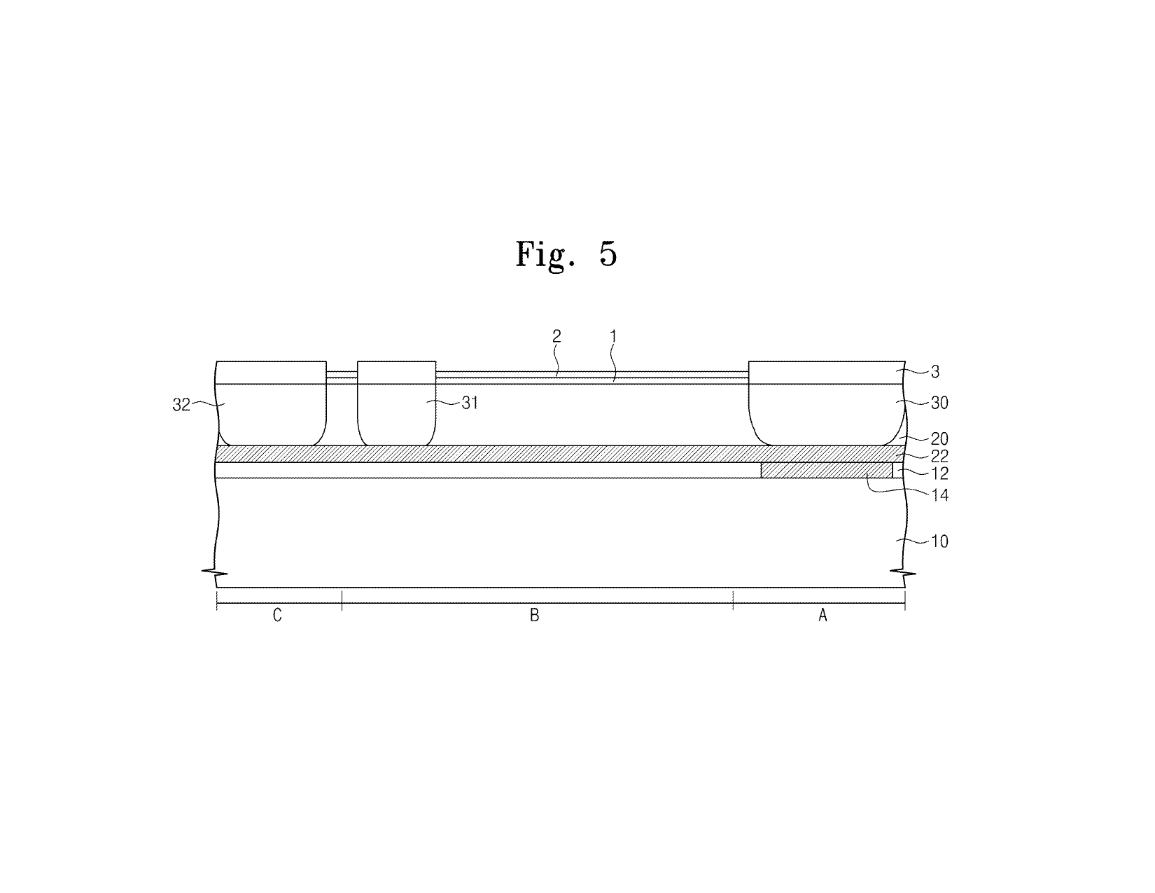

Referring to FIG. 5, first and second deep n-wells 30 and 31 and a collector 32 may be formed in the upper substrate 20. For example, the first deep n-well 30 may be formed in the first region A, the second deep n-well 31 may be formed in the second region B, and the collector 32 may be formed in the third region C. The first and second deep n-wells 30 and 31 and the collector 32 may be formed by implanting n-type dopant ions (e.g., phosphorus ions) into the upper substrate 20 using the patterned nitride layer 2 as an ion implantation mask. The first and second deep n-wells 30 and 31 and the collector 32 may be formed simultaneously.

In some embodiments, the first and second deep n-wells 30 and 31 and the collector 32 may be in contact with the lower doped layer 22. In other words, the first deep n-well 30 may be formed to be in contact with the lower doped layer 22 in the first region A, the second deep n-well 31 may be formed to be in contact with the lower doped layer 22 in the second region B, and the collector 32 may be formed to be in contact with the lower doped layer 22 in the third region C.

Subsequently, a thick oxide layers 3 may be formed on the first and second deep n-wells 30 and 31 and the collector 32, respectively. The thick oxide layers 3 may be formed by a local oxidation of silicon (LOCOS) process. The thick oxide layers 3 may be thicker than each of the oxide layer 1 and the nitride layer 2.

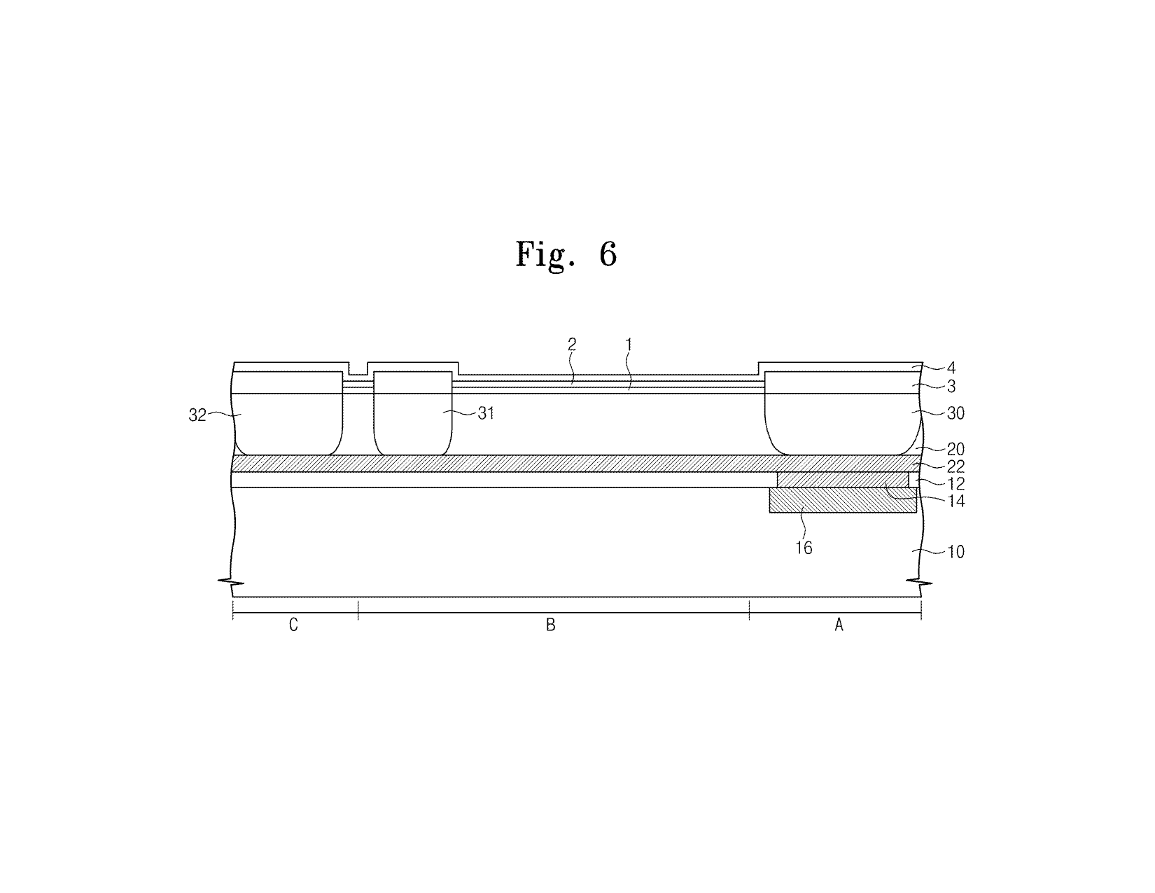

Referring to FIG. 6, a buried doped layer 16 may further be formed in the lower substrate 10. In some embodiments, the buried doped layer 16 in the lower substrate 10 in the first region A. Forming the buried doped layer 16 may include forming a capping oxide layer 4 covering the nitride layer 2 and the thick oxide layer 3. The capping oxide layer 4 may protect the upper substrate 20 in a subsequent thermal treatment process. The thermal treatment process may be performed on the upper substrate 20 having the capping oxide layer 4. Dopants in the epitaxial layer 14 may be diffused into the lower substrate 10 under the epitaxial layer 14 to form the buried doped layer 16 in the first region A. The buried oxide layer 16 may be in contact with the epitaxial layer 14.

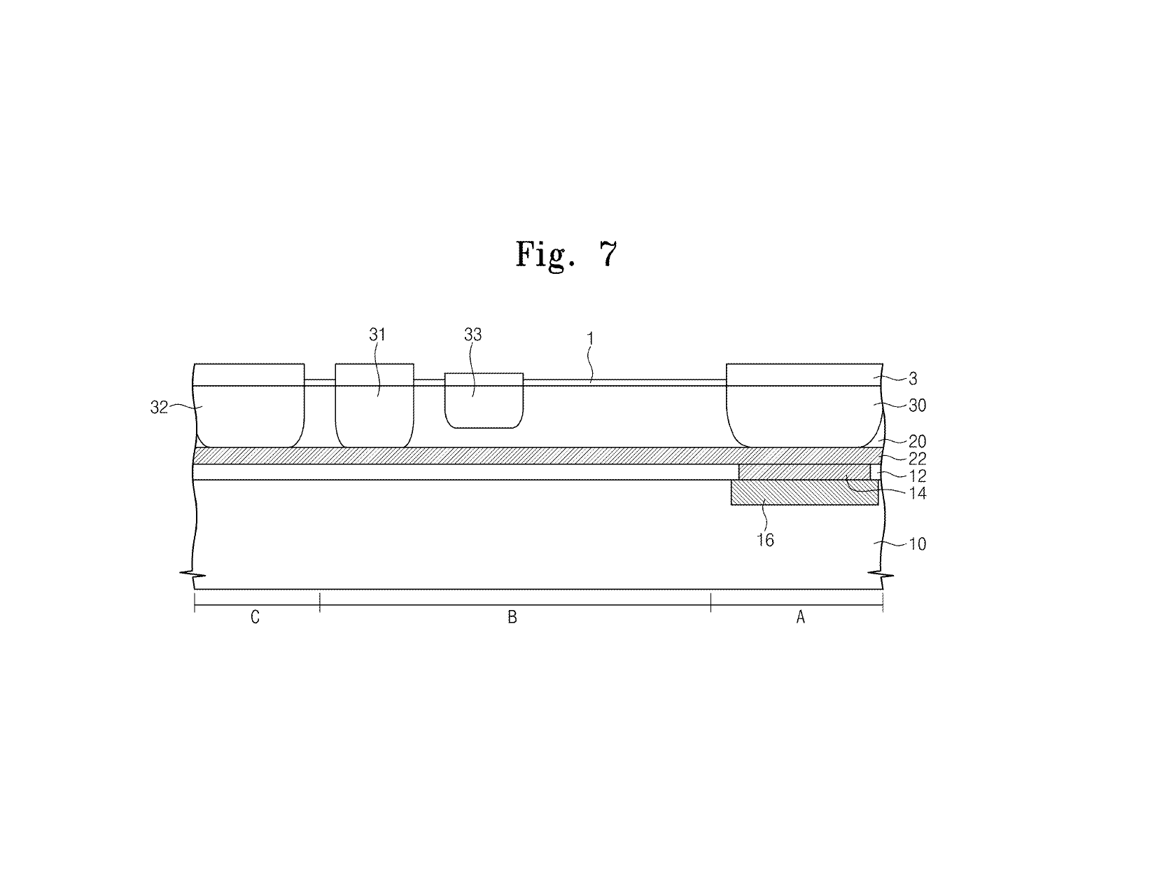

Referring to FIG. 7, the capping oxide layer 4 may be removed and then an n-well 33 may be formed in the upper substrate 20. In some embodiments, the n-well 33 may be formed in the second region B. Forming the n-well 33 may include patterning the nitride layer 2 in the second region B to expose a portion of the oxide layer 1 and implanting phosphorus ions into the upper substrate 20 using the patterned nitride layer 2 as an ion implantation mask. In other embodiments, the oxide layer 1 may be patterned with the nitride layer 2 to expose the upper substrate 20 in the second region B, and then the phosphorus ions may be implanted into the upper substrate 20 to form the n-well 33.

The n-well 33 may be formed in the upper substrate 20 and be spaced apart from the lower doped layer 22. Subsequently, an oxide layer may be grown on the n-well 33 and then a thermal treatment process may further be performed.

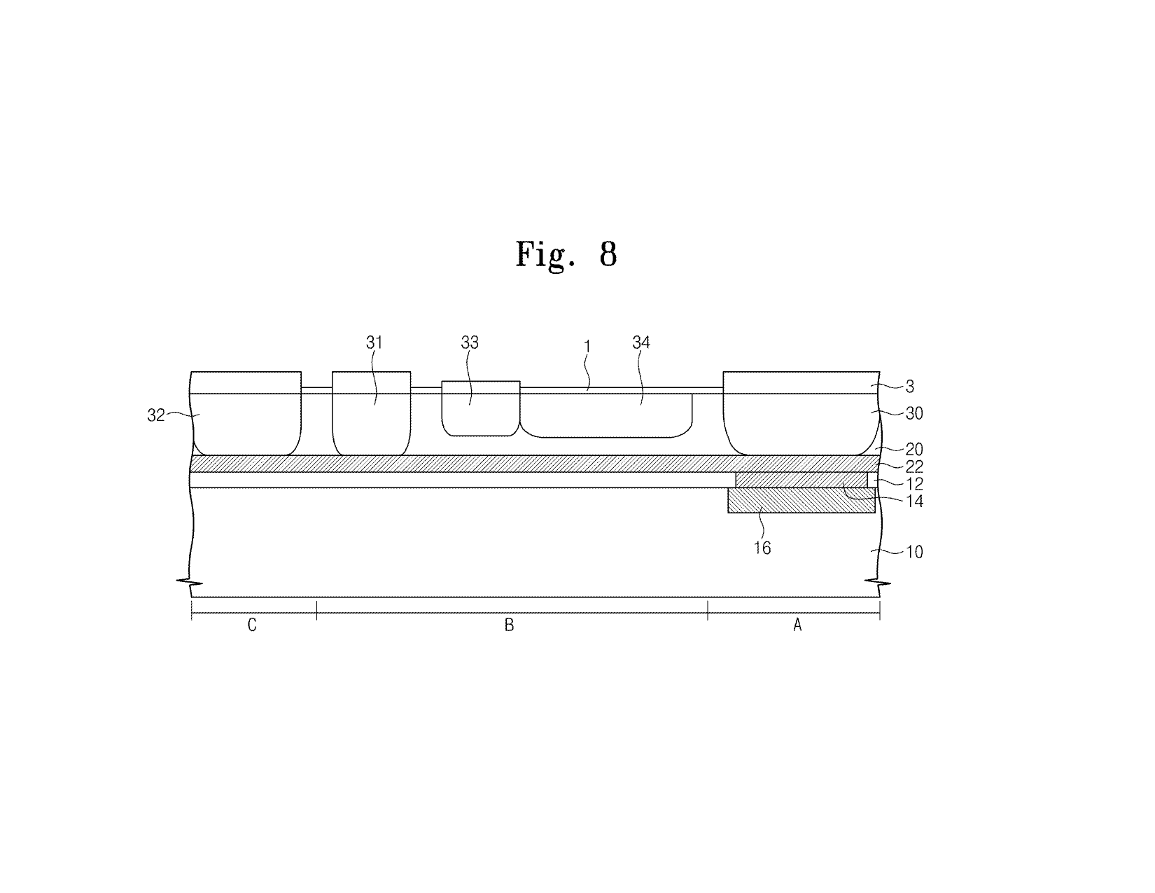

Referring to FIG. 8, a p-well 34 may be formed in the upper substrate 20. In some embodiments, the p-well 34 may be formed in the second region B. Forming the p-well 34 may include forming a photoresist pattern defining the p-well 34 of the second region B, patterning the nitride layer 2 of FIG. 6 in the second region B using the photoresist pattern to expose a portion of the oxide layer 1, and implanting p-type dopant ions (e.g., boron ions) into the upper substrate 20 in the second region B using the patterned nitride layer and/or the photoresist pattern. Thus, the p-well 34 doped with the boron may be formed in the second region B. The p-well 34 may be formed in the upper substrate 20 and be spaced apart from the lower doped layer 22. Subsequently, the nitride layer 2 of FIG. 6, the oxide layer 1 and the thick oxide layer 3 may be removed.

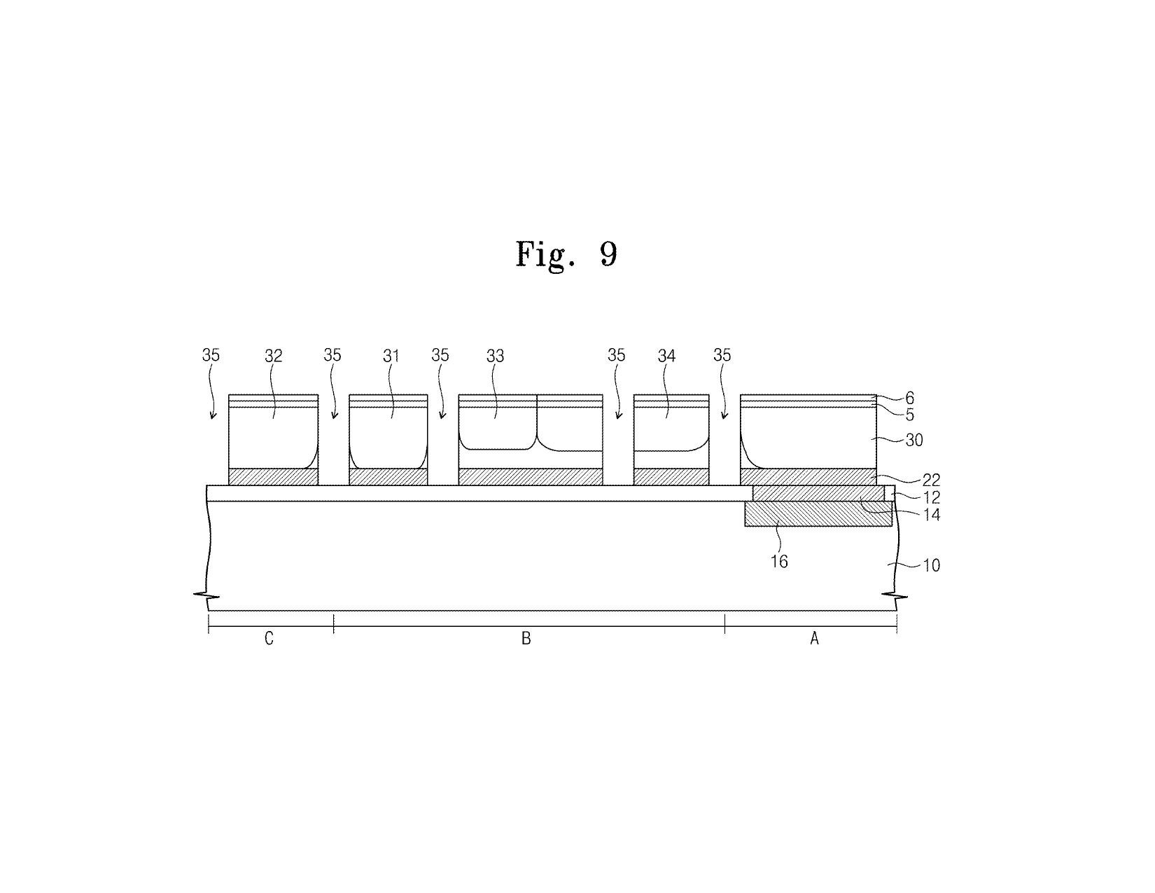

Referring to FIG. 9, trenches 35 for device isolation patterns may be formed in the upper substrate 20. Forming the trenches 35 may include depositing an oxide layer 5 and a nitride layer 6 and successively patterning the nitride layer 6 and the oxide layer 5 to expose portions of the upper substrate 20. Next, the upper substrate may be anisotropically etched using the patterned nitride layer 6 as an etch mask to form the trenches 35. The trenches 35 may penetrate the lower doped layer 22 and expose the insulating layer 12 formed on the lower substrate 10.

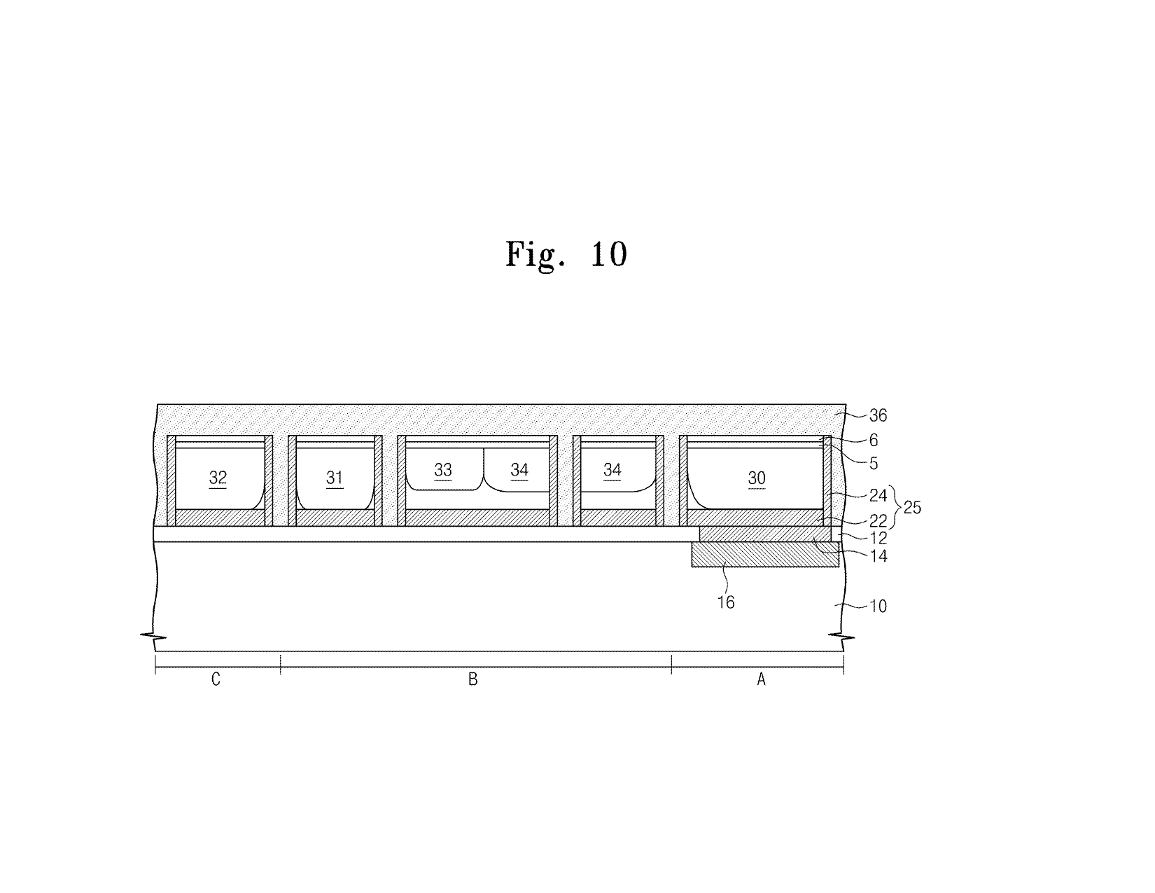

Referring to FIG. 10, sidewall doped layers 24 may be formed on sidewalls of the trenches 35, respectively. The sidewall doped layer 24 may be doped to have a high dopant concentration (e.g., n⁺-type). The sidewall doped layer 24 may be formed by a method using phosphorus silica glass (PSG), a method using boron silica glass (BSG), an ion implantation method, a plasma doping method, or a high concentration epitaxial growth/diffusion method.

In some embodiments, forming the sidewall doped layer 24 may include depositing a PSG thin film having phosphorus of a high concentration in the trenches 35 and performing a thermal treatment on the PSG thin film. Thereafter, the PSG thin film in the trenches 35 may be partially removed. In other words, the PSG thin film conformally formed in the trenches 35 may be anisotropically etched until the insulating layer 12 is exposed. At this time, portions of the PSG thin film may respectively remain the sidewalls of the trenches 35, such that the sidewall doped layers 24 may be formed. The lower doped layer 22 and the sidewall doped layers 24 may be included in doped patterns 25.

A device isolation insulating layer 36 may be formed to fill the trenches 35. The device isolation insulating layer 36 may include an oxide layer, a nitride layer, a mixture oxide layer, or a multi-oxide layer.

For example, the device isolation insulating layer 36 may include a tetra ethyl ortho silicate (TEOS) layer. The device isolation insulating layer 36 may be an insulating layer not including dopants. The device isolation insulating layer 36 may fill the trenches 35 having the sidewall doped layers 24.

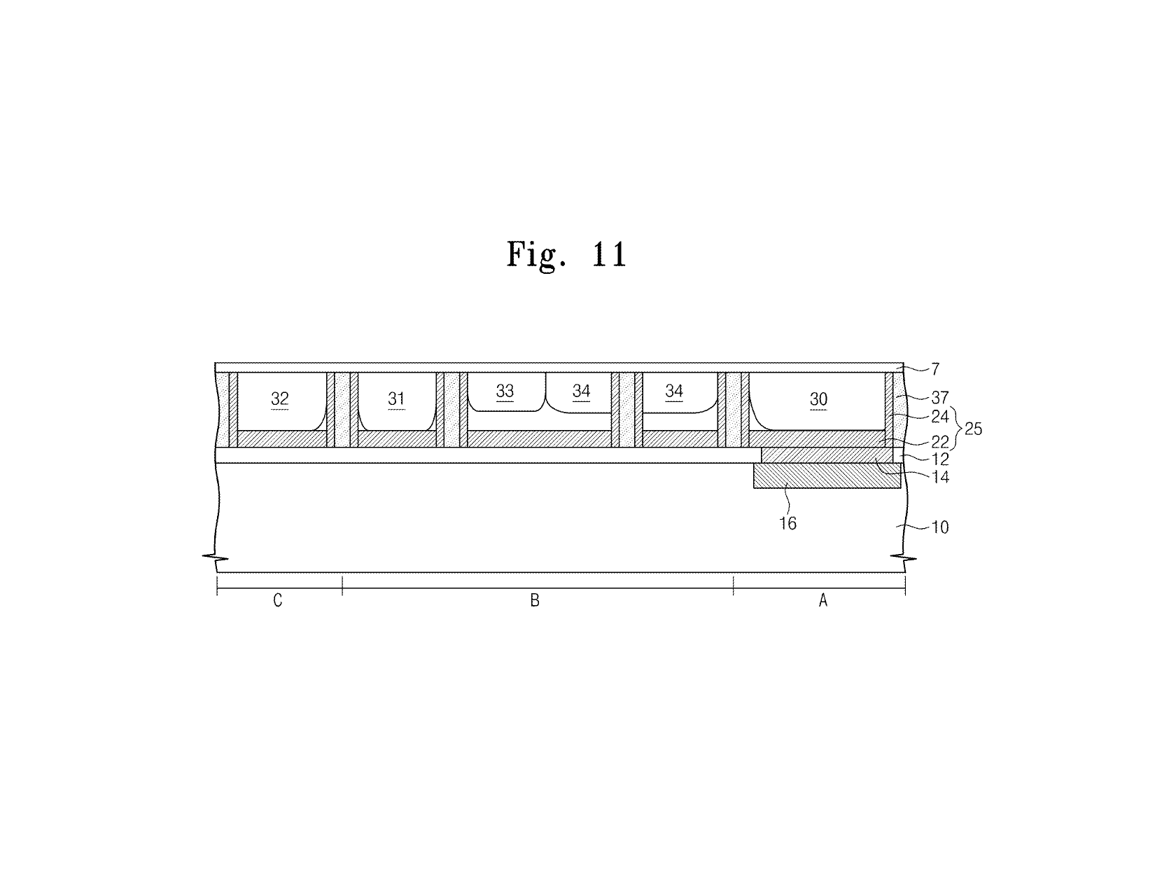

Referring to FIG. 11, a polishing process may be performed to remove a portion of the device isolation insulating layer 36. The polishing process may be performed until the top surface of the upper substrate 20 is exposed. The polishing process may be performed using a chemical mechanical polishing (CMP) method. In this case, the oxide layer 5 and the nitride layer 6 may also be removed.

Thus, as illustrated in FIG. 11, device isolation patterns 37 may be formed in the trenches 35. An oxide layer 7 may further be formed on the upper substrate 20 having the device isolation patterns 37 and the doped patterns 25. The device isolation patterns 37 and the doped patterns 25 may isolate elements from each other.

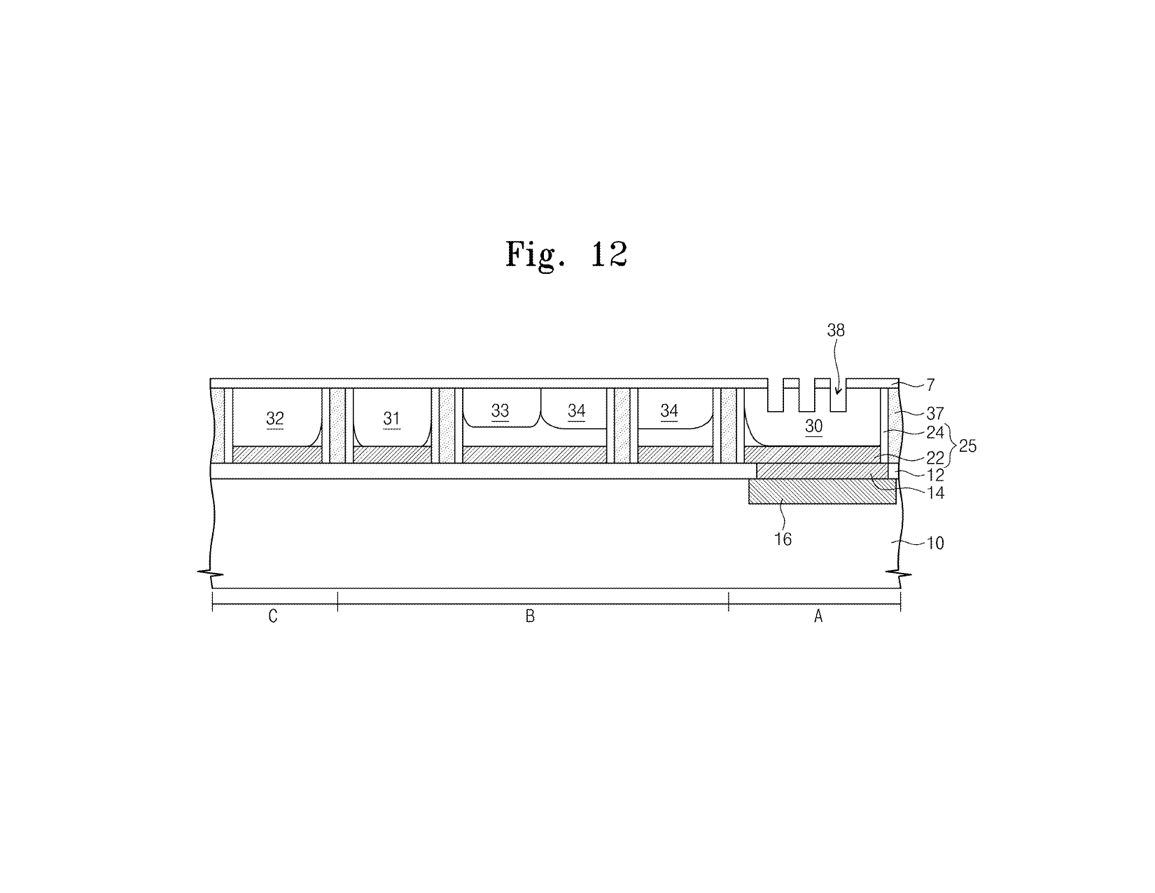

Referring to FIG. 12, one or more gate trenches 38 may be formed in the first region A. The gate trenches 38 may be formed in the upper substrate 20 of the first region A.

In some embodiments, the gate trenches 38 may be formed using the oxide layer 7 as an etch mask layer. The oxide layer 7 may be formed of a TEOS oxide layer.

The gate trenches 38 may be formed by performing a photolithography process to form openings defining the gate trenches 38 and dry-etching the oxide layer 7 and the upper substrate 20 under the openings. The gate trenches 38 may be formed in the first deep n-well 30 in the upper substrate 20.

Additionally, a cleaning process using a sulfuric acid solution may be performed for removing residues such as polymer in the gate trenches 38.

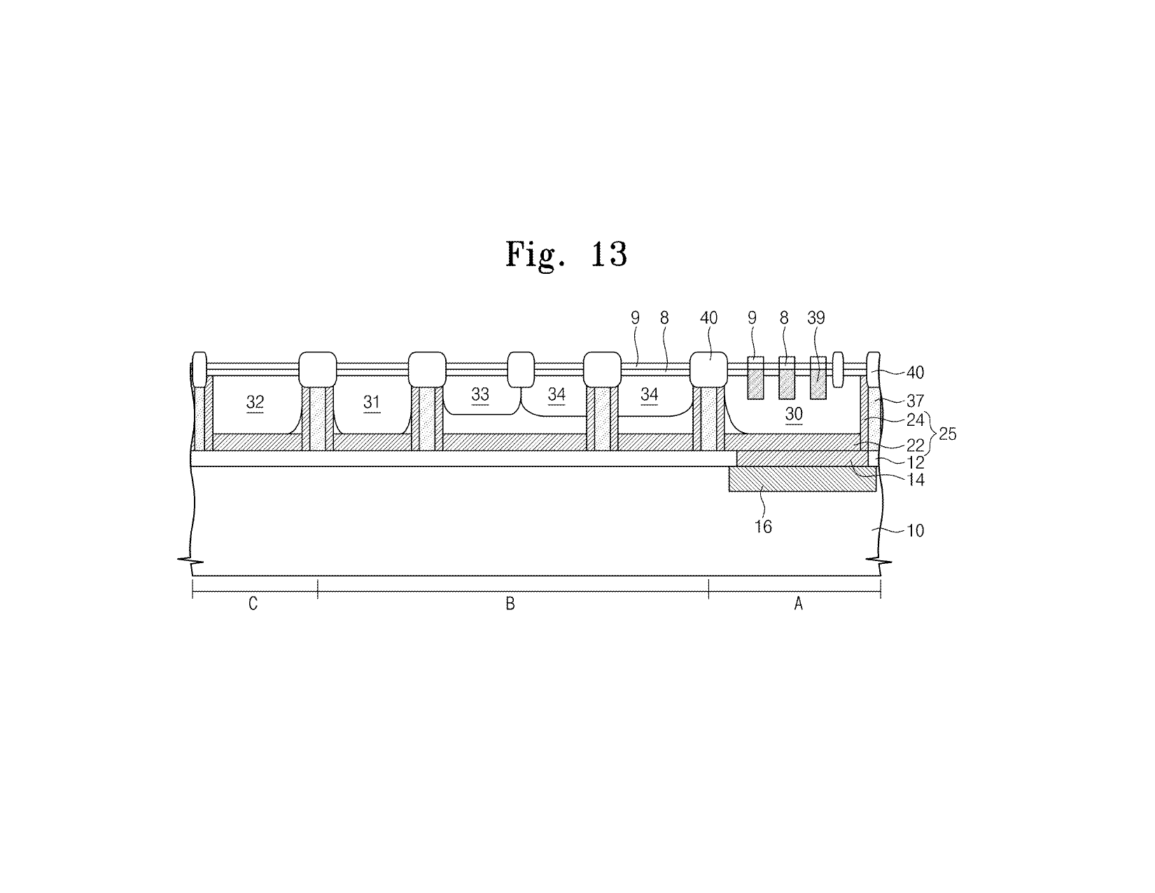

Referring to FIG. 13, trench type gate electrodes 39 may be formed in the gate trenches 38, respectively. A gate oxide layer may be formed in the gate trenches 38 and then the trench type gate electrodes 39 may be formed on the gate oxide layer in the gate trenches 38.

In some embodiments, a poly-crystalline layer doped with phosphorus may be deposited on the upper substrate 10 having the gate trenches 38 and then the poly-crystalline layer may be dry-etched to form the trench type gate electrodes 39. An oxide layer 8 and a nitride layer 9 may be sequentially formed on the upper substrate 20 in which the trench type gate electrodes 39 are formed.

Field oxide layers 40 may be formed on the upper substrate 20. Forming the field oxide layers 40 may include etching the nitride layer 9 on the device isolation patterns 37 and forming the field oxide layers 40. The field oxide layers 40 may be formed by a LOCOS process and be thicker than the oxide layer 8.

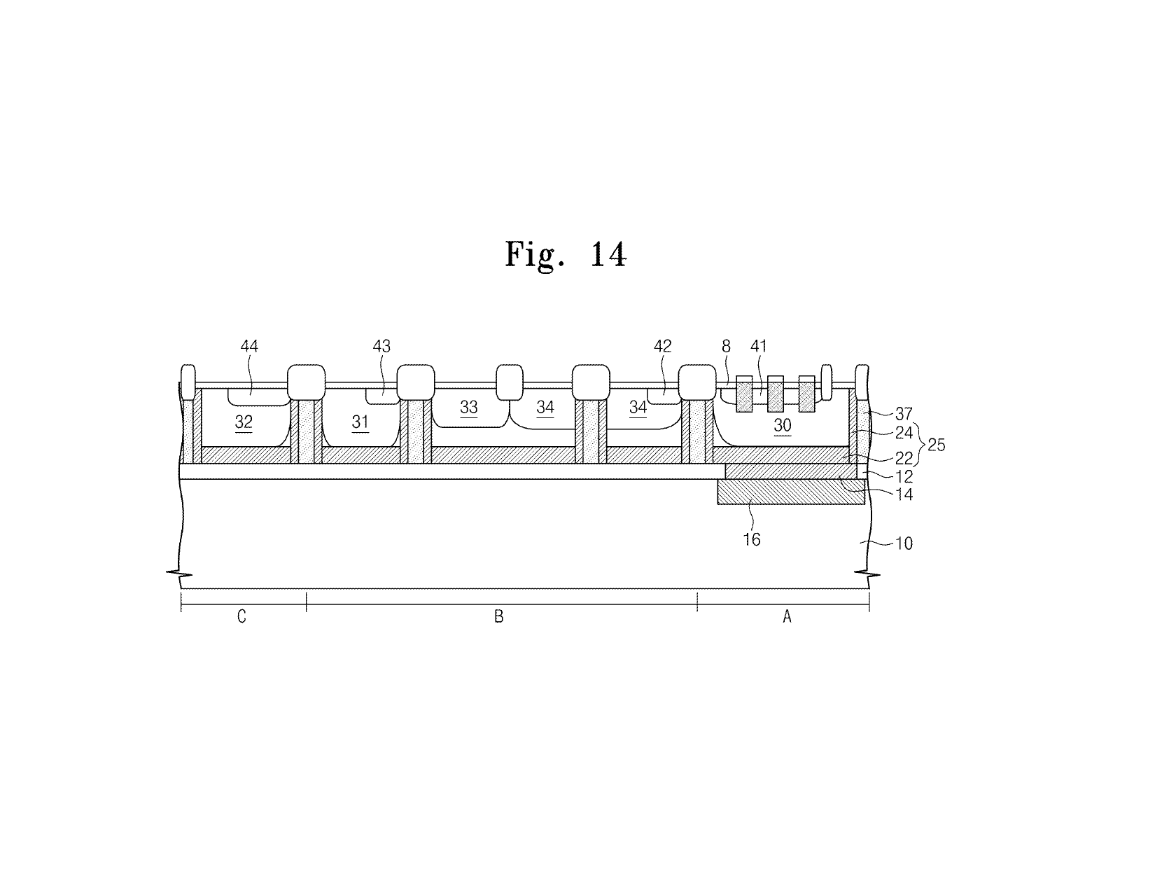

Referring to FIG. 14, an n-drift region 42 may be formed in the upper substrate 20. The n-drift region 42 may be formed in the p-well 34 formed in the second region B. Forming the n-drift region 42 may include pattering the nitride layer 9 of FIG. 13 to expose a portion of the p-well 34 and implanting dopant ions (e.g., phosphorus ions) into the exposed portion of the p-well 34.

A p-body region 41, a p-drift region 43, and a base 44 may be formed in the upper substrate 20. For example, the p-body region 41 may be formed in the first deep n-well 30 in the first region A. The p-drift region 43 may be formed in the second deep n-well 31 in the second region B. The base 44 may be formed in the collector 32 in the third region C. Forming the p-body region 41, the p-drift region 43, and the base 44 may include patterning the nitride layer 9 of FIG. 13 to expose portions of the first deep n-well 30, the second deep n-well 31, and the collector 32 and implanting dopant ions (e.g., boron ions) into the exposed portions of the first deep n-well 30, the second deep n-well 31, and the collector 32.

A bottom surface of the p-body region 41 may be disposed at a level higher than bottom surfaces of the trench-type gate electrodes 39.

The p-body region 41, the p-drift region 43, and the base 44 may be formed simultaneously.

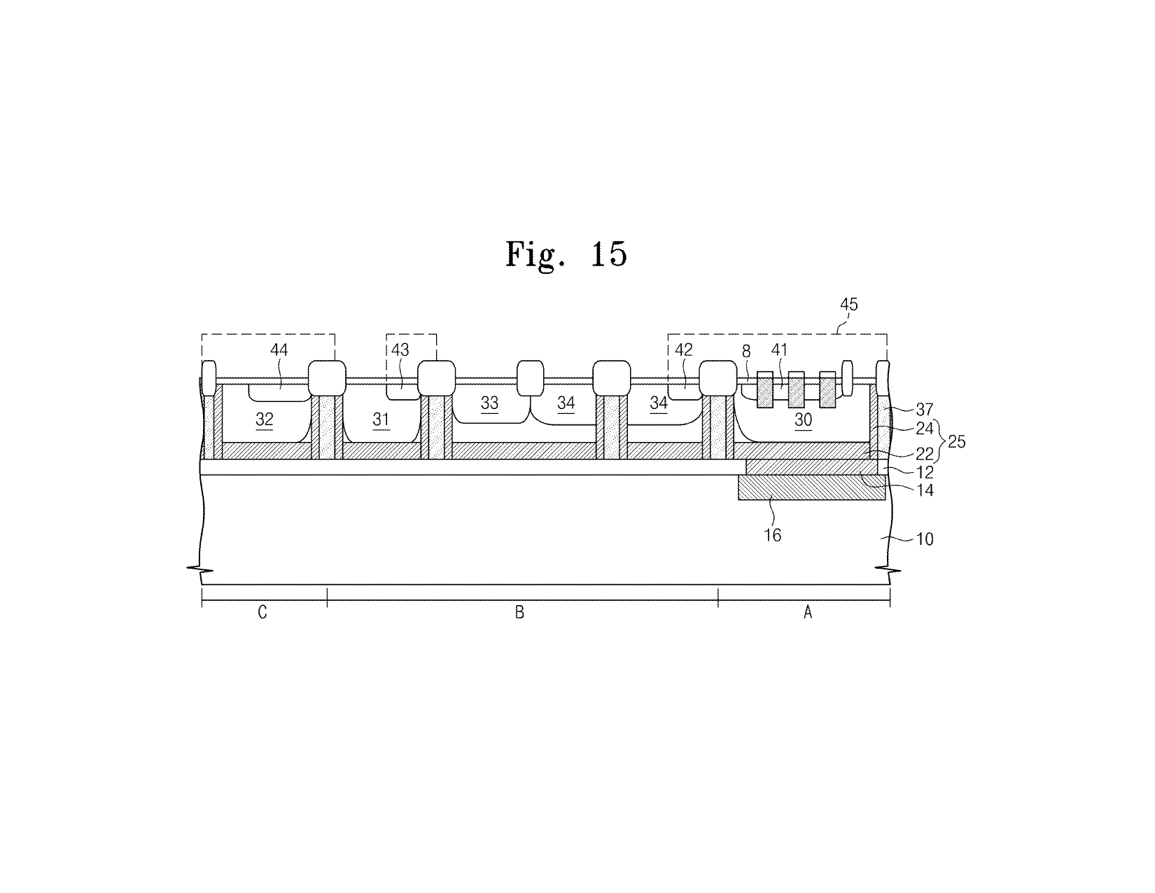

Referring to FIG. 15, a doping process may be performed for threshold voltage control. For example, the doping process may be performed on at least one of the first to third regions A, B, and C. After a photoresist pattern 45 may be formed to expose at least one of the first to third region A, B, and C, boron ions or phosphorus ions may be implanted using the photoresist pattern 45 as an ion implantation mask into the upper substrate 20 in at least one of the first to third regions A, B, and C. Threshold voltages of first to third elements respectively formed in the first to third regions A, B, and C may be controlled into desired ranges by the doping process for the threshold voltage control. Subsequently, the photoresist pattern 45 may be removed.

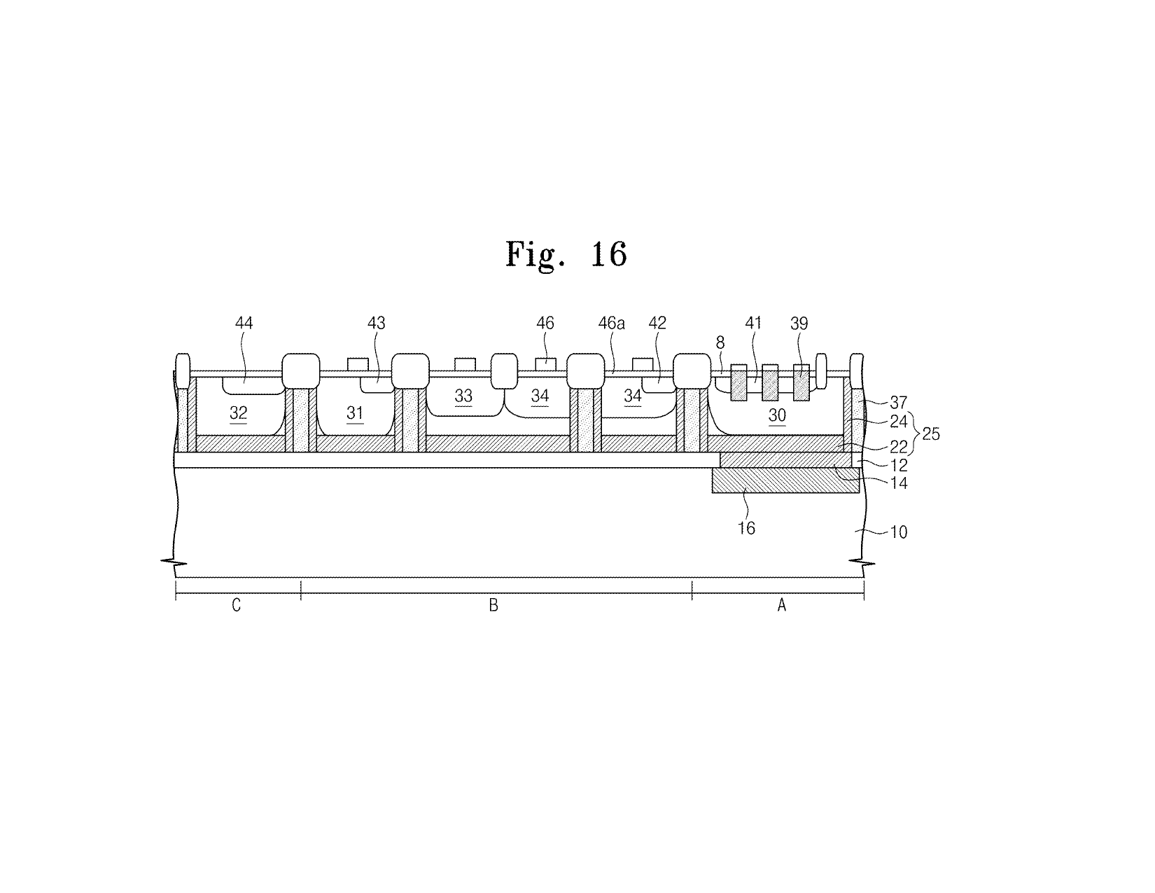

Referring to FIG. 16, gate electrodes 46 may be formed on the upper substrate 20. For example, the gate electrodes 46 may be formed in the second region B. Forming the gate electrodes 46 may include forming a gate oxide layer 46a on the upper substrate 20. The gate oxide layer 46a may be formed on selected regions in the second region B. In some embodiments, after the remaining oxide layer 8 of FIG. 15 may be wet-etched, a dry-oxidation process may be performed to form the gate oxide layer 46.

The gate electrodes 46 may be formed on the gate oxide layer 46a. A poly-crystalline silicon layer including phosphorus may be deposited on the gate oxide layer 46a and then mask patterns may be formed on the poly-crystalline silicon layer by a photolithography process. Thereafter, the poly-crystalline silicon layer may be etched using the mask patterns, thereby forming the gate electrodes 46.

Even though not shown in the drawings, a sidewall oxide layer may be formed on sidewalls of the gate electrodes 46. For example, a TEOS oxide layer may be deposited on an entire surface of the upper substrate 20 and then the TEOS oxide layer may be dry-etched to form the sidewall oxide layer. In some embodiments, after the sidewall oxide layer is formed, an oxide layer (not shown) may further be formed to cover the trench type gate electrodes 39 of the first region A.

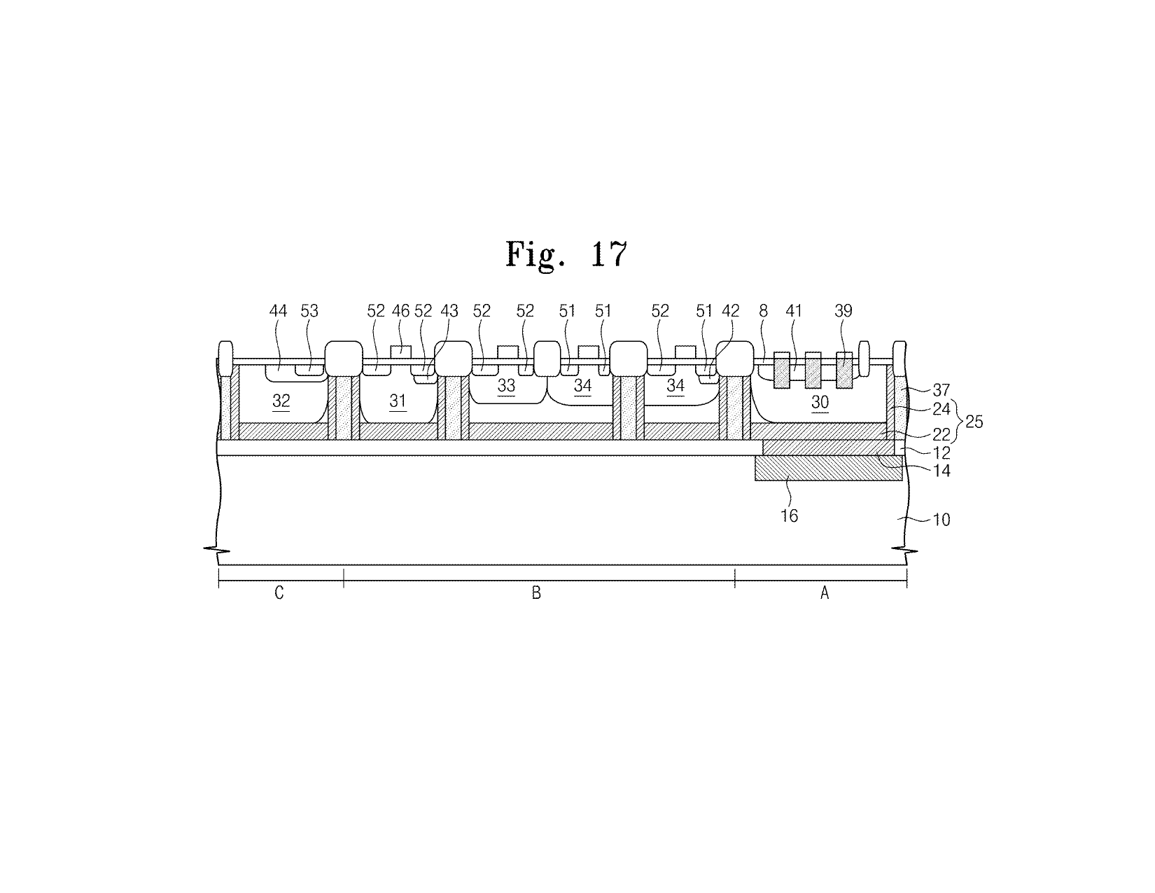

Referring to FIG. 17, n-LDD regions 51 and an emitter 53 may be formed in the upper substrate 20. The n-LDD regions 51 may be formed in the p-well 34 of the second region B, and the emitter 53 may be formed in the base 44 of the third region C. The n-LDD regions 51 and the emitter 53 may be formed by a doping process using an n-type source drain (NSD) mask (not shown). For example, the NSD mask may be formed on the upper substrate 20 by a photolithography process and then phosphorus ions may be implanted using the NSD mask as an ion implantation mask into the upper substrate 20, thereby forming the n-LDD regions 51 and the emitter 53.

P-LDD regions 52 may be formed in the upper substrate 20. The p-LDD regions 52 may be formed in the second deep n-well 31, the n-well 33, and the p-well 34 in the second region B. The p-LDD regions 52 may be formed by a doping process using a p-type source drain (PSD) mask. For example, the PSD mask may be formed on the upper substrate 20 by a photolithography process and then boron ions may be implanted using the PSD mask as an ion implantation mask into the upper substrate 20, thereby forming the p-LDD regions 52.

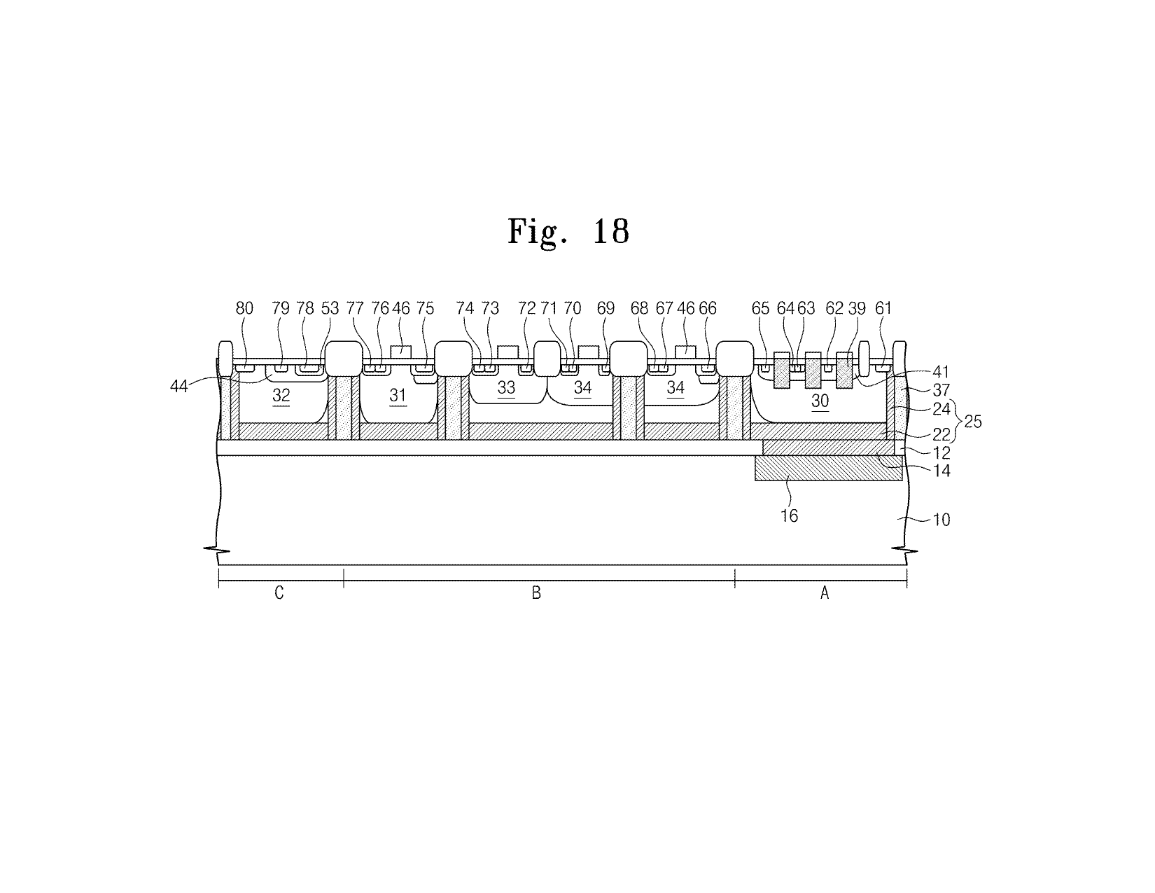

Referring to FIG. 18, an n⁺ source 64, a p⁺ junction 63 and 65, a p⁺ ground 62, and an n⁺ drain 61 may be formed in the upper substrate 20 in the first region A. The n⁺ source 64, the p⁺ junction 63 and 65, and the p⁺ ground 62 may be formed in the p-body region 41 in the first region A and be formed between the trench type gate electrodes 39.

The n⁺ drain 61 may be formed in the first deep n-well 30 and be spaced apart from the p-body region 41. The n⁺ drain 61 may be in contact with the sidewall doped layer 24. In other words, the n⁺ drain 61 may be formed to be in contact with the sidewall doped layer 24 in the first region A, such that the n⁺ drain 61 may be electrically connected to the first deep n-well 30, the lower doped layer 22, the epitaxial layer 14, and the buried doped layer 16.

Source/drain regions 66 to 77 may be formed in the second region B. The source/drain regions 66 to 77 may be formed in the n-well 33 and p-well 34 in the second region B. For example, n⁺ drains 66 and 69, n⁺ sources 67 and 70, and p⁺ contacts 68 and 71 may be formed in the p-well 34. And a p⁺ drain 75, a p⁺ source 76, and an n⁺ contact 77 may be formed in the second deep n-well 31.

An emitter contact 78, a base contact 79, and a collector contact 80 may be formed in the upper substrate 20 of the third region C. The emitter contact 78 may be formed in the emitter 53, the base contact 79 may be formed in the base 44, and the connector contact 80 may be formed in the collector 32. The collector contact 80 may be formed to be in contact with the sidewall doped layer 24. In other words, the collector contact 80 may be in contact with the sidewall doped layer 24 in the third region C, so that the collector contact 80 may be electrically connected to the collector 32 and the lower doped layer 22.

The n⁺ source 64, the p⁺ junction 63 and 65, the p⁺ ground 62, and the n⁺ drain 61 in the first region A, the source/drain regions 66 to 77 in the second region B, the emitter contact 78, the base contact 79, and the collector contact 80 in the third region C may be formed by an ion implantation process using a PSD mask and an ion implantation process using an NSD mask.

Referring to FIG. 19, an interlayer insulating layer 81 may be formed to cover the upper substrate 20 and then metal interconnections 82, 83, and 84 may be formed to penetrate the interlayer insulating layer 81. Forming the interlayer insulating layer 81 may include depositing a TEOS oxide layer and/or a borophospho silicate glass (BPSG) oxide layer, performing a thermal treatment on the deposited TEOS oxide layer and/or BPSG oxide layer, and planarizing the thermally treated TEOS oxide layer and/or BPSG oxide layer.

First metal interconnections 82 may be electrically connected to the trench type gate electrodes 39, the n⁺ source 65, the p⁺ junction 63, and the n⁺ drain 61 in the first region A. Second metal interconnections 83 may be electrically connected to the gate electrodes 46 and the source/drains in the second region B. Third metal interconnections 84 may be electrically connected to the emitter contact 78, the base contact 79, and the collector contact 80 in the third region C. The metal interconnections 82, 83, and 84 may be aluminum metal interconnections.

Thereafter, a grinding process may be performed to partially remove a back side of the lower substrate 10. After a taping process may be performed to stick a tape on a front side of the upper substrate 20 for protecting the front side of the upper substrate 20, the back side of the upper substrate 10 may be grinded by the grinding process. Thus, the resultant structure including the lower and upper substrate 10 and 20 and the metal interconnections 82, 83, and 84 may become thin.

By the processes described above, elements different from each other may be formed in the first to third regions A, B, and C, respectively.

The first region A may be a first element region in which a first element is formed. For example, the first region A may be a double diffused metal-oxide-semiconductor (DMOS) element region. The DMOS element (i.e., a DMOS transistor) may be a trench double diffused metal-oxide-semiconductor (TDMOS) element. The first element may be used as a power control circuit. For example, the first element may be used as a high-current switch.

The second region B may be a second element region in which a second element is formed. For example, the second region B may be a complementary metal-oxide-semiconductor (CMOS) element region. The CMOS element may include at least one of a PMOS element, an ED-PMOS element, an NMOS element, and an ED-NMOS element. At least one of the CMOS elements may be used as a low-voltage element or a high-voltage element. The second element may be used as a digital element. For example, the second element may be used as a signal control circuit.

The third region C may be a third element region in which a third element is formed. For example, the third element may be a bipolar element (i.e., a bipolar transistor). The third element may be used as an analogue element. The third element may be included in a temperature sensor.

If a high bias is applied to a high-voltage element in a general smart power integrated circuit, a low-voltage CMOS element and/or a bipolar element of the general smart power integrated circuit may be broken.

However, according to embodiments of the inventive concept, the isolation structures may be provided between the first, second, and third elements, so that the semiconductor device having high reliability may be realized. For example, if a high bias is applied to the first element in the first region A, a current may flow through the first deep n-well 30, the doped patterns 25, the epitaxial layer 12, and the buried doped layer 16. On the contrary, it is possible to prevent the current from flowing to the second and third regions B and C by the device isolation patterns 37, the insulating layer 12, and the doped patterns 25. Thus, it is possible to prevent the current from flowing into the second and third elements of the second and third regions B and C, so that control circuits of the semiconductor device may become stable.

Additionally, since the first element of the first region A includes the n⁺ drain 61 which is formed in the upper substrate 20 and is in contact with the sidewall doped layer 24, the first metal interconnection 82 is disposed over the top surface of the upper substrate 20 and is connected to the n⁺ drain 61. Thus, it is possible to prevent the current from flowing into the second and third elements of the second and third regions B and C, so that the control circuit may become stable.

In other embodiments, a current applied to each of the second and third elements in the second and third regions B and C may be prevented from flowing to other elements by the insulating layer 12 on the lower substrate 10 and the doped patterns 25 formed in each of the second and third regions B and C. Thus, the control circuit may become stable.

Alternatively, a drain may be formed on the back side of the lower substrate 10. In this case, the first element may allow a current to flow through the lower substrate 10 but prevent a current from flowing to the second and third regions B and C. Here, the lower substrate 10 may be doped with n-type dopants. The drain may be formed by implanting phosphorus ions into the back side of the lower substrate 10. A metal interconnection electrically connected to the drain may be formed on the back side of the lower substrate 10.

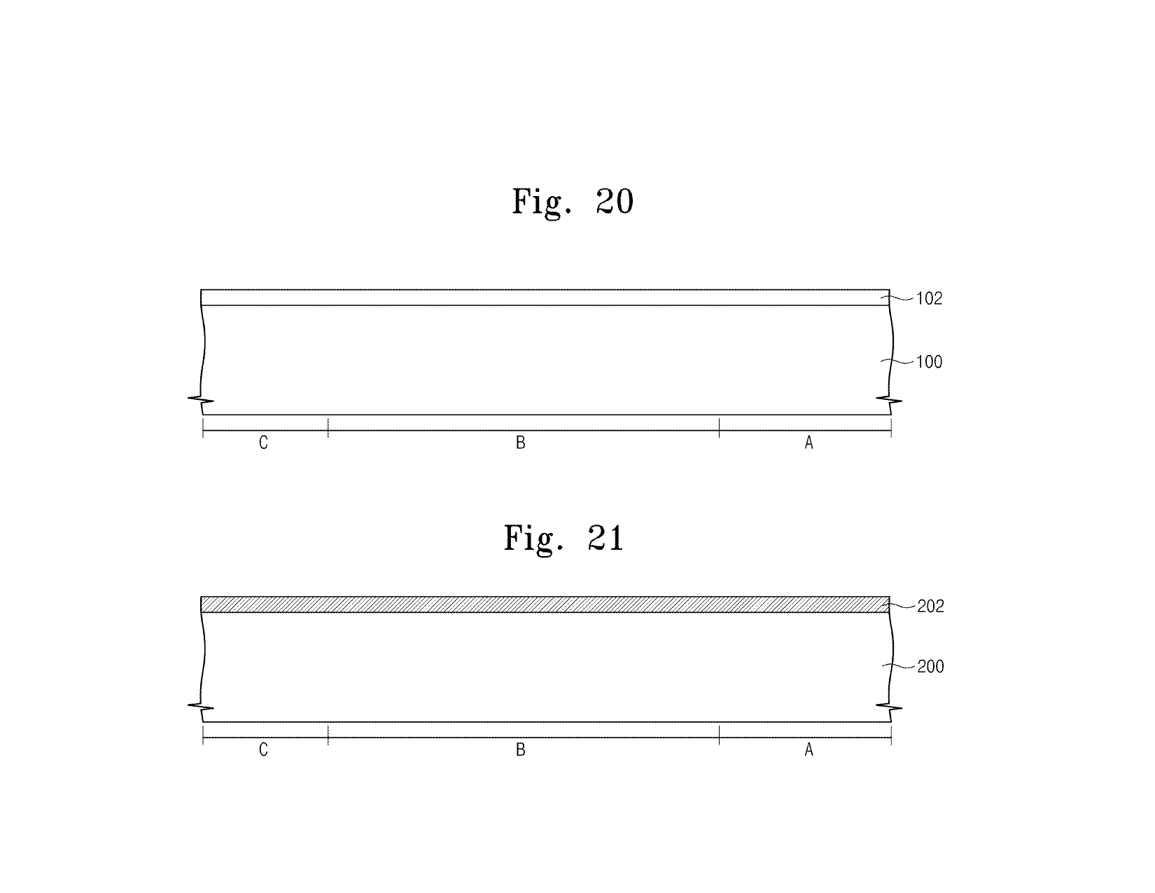

FIGS. 20 to 24 are cross-sectional views illustrating a method of fabricating a semiconductor device according to other embodiments of the inventive concept.

Referring to FIG. 20, a lower substrate 100 including first to third regions A, B, and C may be provided. The lower substrate 100 may be doped with dopants. For example, the lower substrate 100 may be a p-type substrate. Elements different from each other may be formed in the first to third regions A, B, and C, respectively. An insulating layer 102 may be formed on the lower substrate 100. The insulating layer 102 may be formed of, for example, a silicon oxide layer. The insulating layer 102 may be formed by a deposition process. The insulating layer 102 may be formed on an entire front side of the lower substrate 100.

Referring to FIG. 21, an upper substrate 200 including first to third regions A, B, and C may be provided. The upper substrate 200 may be doped with dopants. For example, the upper substrate 200 may be a p-type substrate.

A lower doped layer 202 may be formed on the upper substrate 200. The lower doped layer 202 may be formed by an ion implantation process and a diffusion process. The lower doped layer 202 may be doped with dopants of a conductivity type different from that of the upper substrate 200 and have a high dopant concentration. For example, the lower doped layer 202 may be doped in n⁺-type. The lower doped layer 202 may be formed on an entire front side of the upper substrate 200.

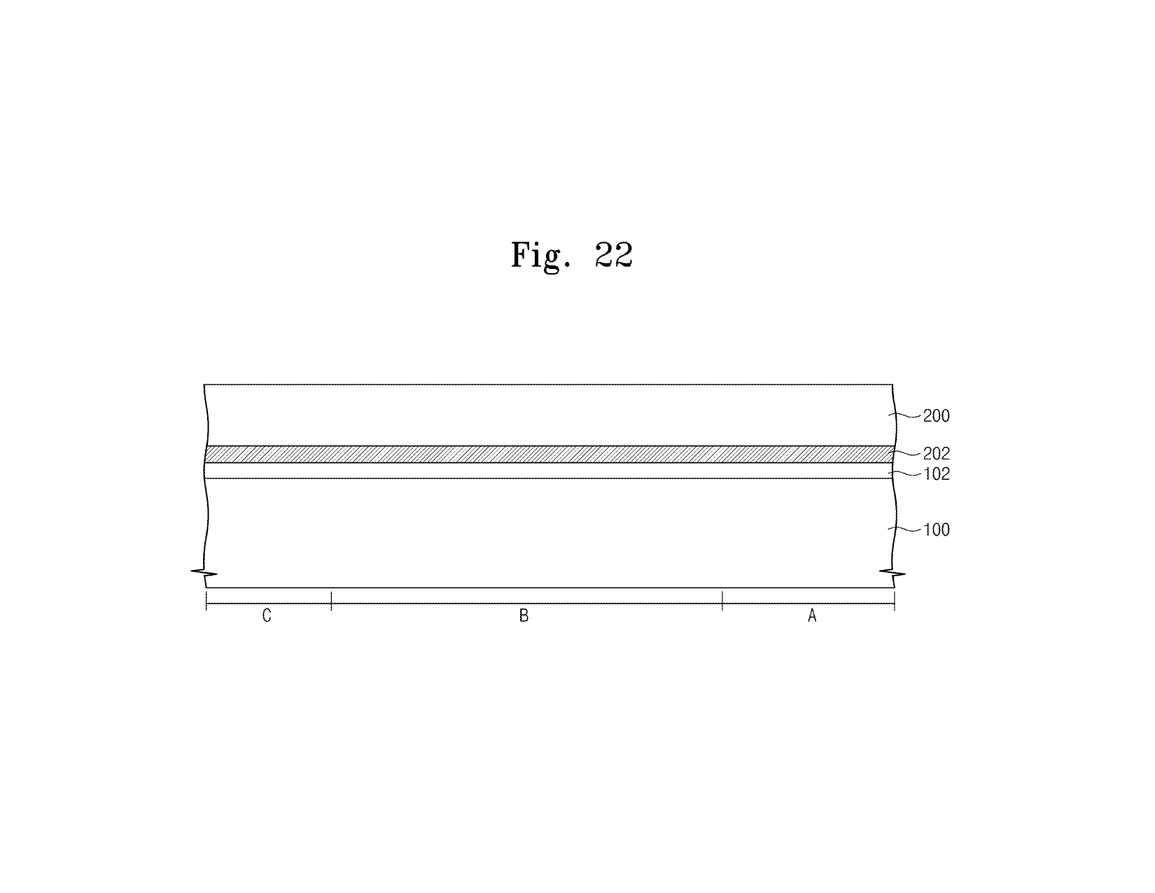

Referring to FIG. 22, the lower substrate 100 and the upper substrate 200 may be bonded to each other. Bonding the lower and upper substrates 100 and 200 may include cleaning the lower and upper substrates 100 and 200. Additionally, bonding the lower and upper substrates 100 and 200 may include overturning the upper substrate 200 and bonding the lower substrate 100 and the upper substrate 200 to bring the lower doped layer 202 of the upper substrate 200 into contact with the insulating layer 102 of the lower substrate 100. Subsequently, a thermal treatment process may be performed on the bonded lower and upper substrates 100 and 200.

Thus, the lower and upper substrates 100 and 200 may be bonded to each other in the state that the insulating layer 102 of the lower substrate 100 is in contact with the lower doped layer 202 of the upper substrate 200.

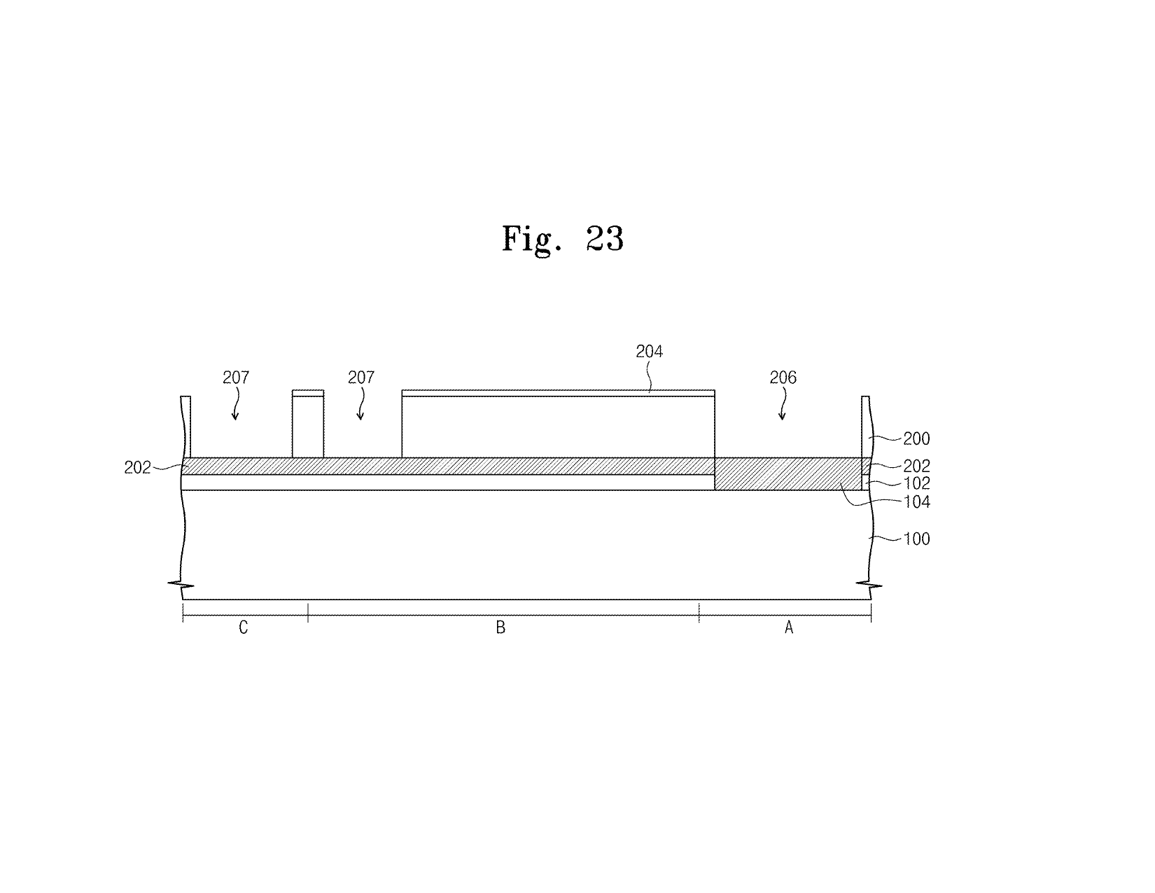

Referring to FIG. 23, an oxide layer 204 may be formed on the upper substrate 200. A first trench 206 may be formed in the first region A. The first trench 206 may penetrate the oxide layer 204, the upper substrate 200, the lower doped layer 202, and the insulating layer 102 to expose the lower substrate 100. A first doped region 104 may be formed in the first trench 206 by a selective epitaxial growth (SEG) process. That is, the first doped region 104 corresponds to an epitaxial layer. The first doped region 104 is in contact with the lower substrate 100. The first doped region 105 may be highly doped with n-type dopants.

Second trenches 207 may be formed in the second and third regions B and C, respectively. The second trenches 207 may penetrate the oxide layer 204 and the upper substrate 200 to expose the lower doped layer 202.

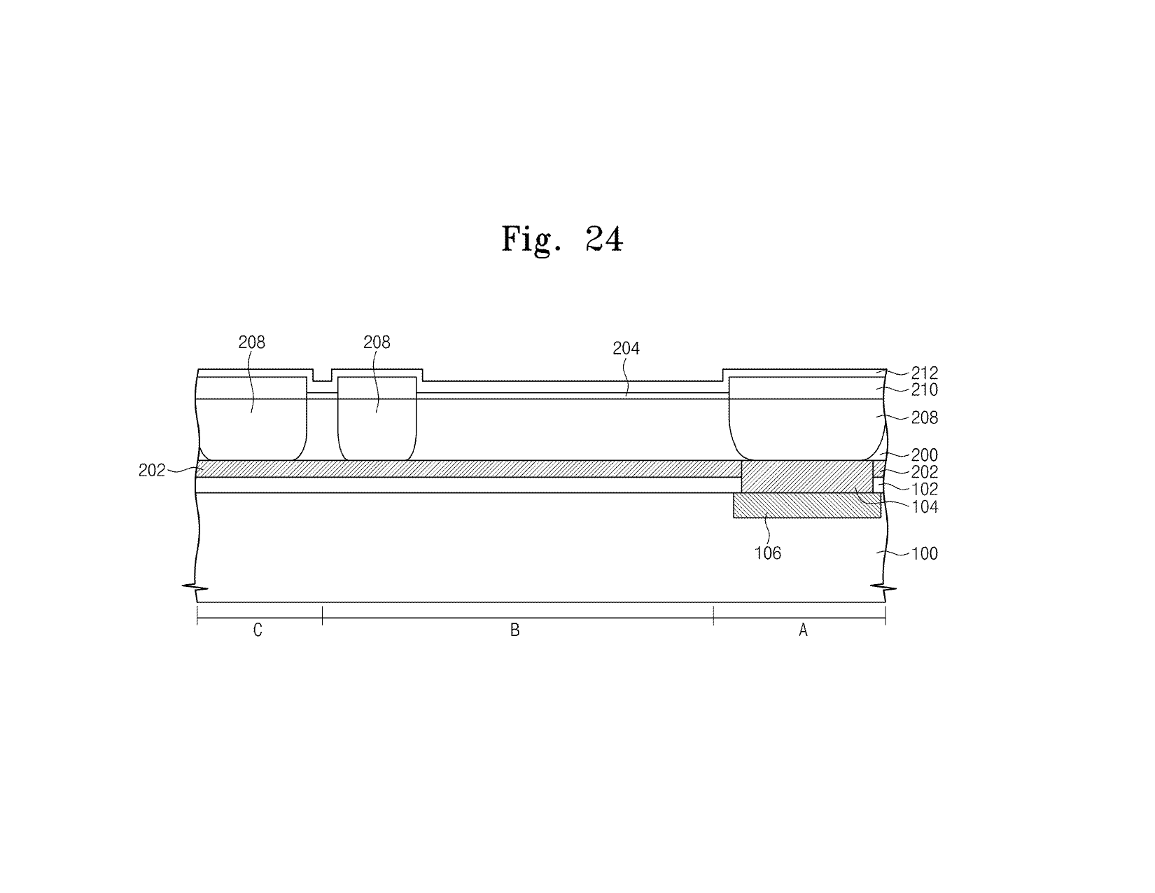

Referring to FIG. 24, deep n-wells 208 may be formed in the trenches 206 and 207, respectively. The deep n-wells 208 may be formed by performing a SEG process in the trenches 206 and 207. The deep n-wells 208 may be doped with n-type dopants (e.g. phosphorus) by an ion implantation process.

For example, when the SEG process is performed, the deep n-well 208 in the first region A may be grown from the first doped region 104 and the deep n-wells 208 in the second and third regions B and C may be grown from the lower doped layer 202.

Subsequently, thick oxide layers 210 may be formed on the deep n-wells 208, respectively. The thick oxide layers 210 may be formed by a LOCOS process. The thick oxide layer 210 may be thicker than the oxide 204.

A second doped region 106 may further be formed in the lower substrate 100 under the first doped region 104. For example, the second doped region 106 may be formed in the first region A. In more detail, a capping oxide layer 212 may be formed to cover the oxide layer 204 and the thick oxide layers 210. The capping oxide layer 212 may protect the substrates 200 and 100 in a subsequent thermal treatment process. A thermal treatment process may be performed on the upper substrate 200 including the capping oxide layer 212. Dopants in the first doped region 106 may be diffused into the lower substrate 100 in the first region A by the thermal treatment process, thereby forming the second doped region 106. The second doped region 106 may be in contact with the first doped region 104. Thereafter, the thermal oxide layer 212 may be removed.

Subsequently, the processes described with reference to FIGS. 7 to 19 may be performed on the resultant structure of FIG. 24.

According to embodiments of the inventive concept, it is possible to provide the smart power IC including the TDMOS power element instead of a conventional vertical double diffused metal-oxide-semiconductor (VDMOS). Thus, it is possible to realize the high current device of small size and excellent current driving capacity.

Additionally, the epitaxial layer and the buried doped region may be disposed in the first region, and the device isolation patterns and the doped patterns may separate the elements from each other. Thus, it is possible to prevent the elements from being broken by a high bias.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. For example, the upper and lower substrates are doped with p-type dopants as an example. Alternatively, the upper and lower substrates may be doped with n-type dopants and doping types of components of the elements may be changed according to the doping states of the substrates. Thus, the scope of the inventive concept is to be determined by the broadest permissible interpretation of the following claims and their equivalents, and shall not be restricted or limited by the foregoing description.

What is claimed is:

1. A semiconductor device comprising:
a substrate having a first region including a first element and a second region including a second element, the substrate including a lower substrate and an upper substrate bonded to each other;
an epitaxial layer and an insulating layer disposed between the lower substrate and the upper substrate, the epitaxial layer disposed in the first region, and the insulating layer disposed in the second region;
a device isolation pattern separating the first element from the second element; and
a doped pattern disposed between the upper substrate and the insulating layer and between the upper substrate and the epitaxial layer,
wherein the first element is electrically connected to the lower substrate through the doped pattern and the epitaxial layer; and
wherein the second element is electrically insulated from the lower substrate by the doped pattern and the insulating layer.

2. The semiconductor device of claim 1, wherein the doped pattern includes a lower doped layer parallel to the lower substrate; and a sidewall doped layer vertically extending from the lower doped layer,
Wherein the sidewall doped layer is in contact with the device isolation pattern.

3. The semiconductor device of claim 1, further comprising:
a buried doped layer disposed in the lower substrate,
wherein the buried doped layer is in contact with the epitaxial layer in the first region.

4. The semiconductor device of claim 1, wherein the upper and lower substrates are doped with dopants of a first conductivity type; and
wherein the epitaxial layer and the doped pattern are doped with dopants of a second conductivity type different from the first conductivity type.

5. The semiconductor device of claim 1, wherein the first element includes a deep well disposed to be in contact with the doped pattern.

6. The semiconductor device of claim 1, wherein the first element is a DMOS transistor.

7. The semiconductor device of claim 1, wherein the first element includes a source, a drain, and a trench type gate; and
wherein the source, the drain, and the trench type gate are connected to metal interconnections disposed on a top surface of the upper substrate.

8. The semiconductor device of claim 1, wherein the second element includes at least one well spaced apart from the doped pattern.

9. The semiconductor device of claim 1, wherein the second element is a CMOS element.

10. The semiconductor device of claim 1, wherein the substrate further includes a third region including a third element; and
wherein the third element is a bipolar transistor.

11. A method of fabricating a semiconductor substrate, comprising:
forming an insulating layer on a lower substrate having first to third regions;
forming an epitaxial layer on the lower substrate of the first region;
forming a lower doped layer on an upper substrate having first to third regions;
bonding the upper substrate to the lower substrate to bring the epitaxial layer and the insulating layer into contact with the lower doped layer;
forming a deep well in the upper substrate of the first region;
forming at least one well in the upper substrate of the second region;
forming trenches penetrating the upper substrate and the lower doped layer;
forming side wall layers on sidewalls of the trenches, respectively; and
forming device isolation patterns filling the trenches, respectively.

12. The method of claim 11, wherein forming the epitaxial layer includes:
patterning the insulating layer to expose the lower substrate in the first region; and
performing a selective epitaxial growth process to form the epitaxial layer.

13. The method of claim 11, wherein the lower doped layer is formed by an ion implantation process and a diffusion process; and
wherein the lower doped layer is doped with dopants of a conductivity type different from that of the upper substrate.

14. The method of claim 11, wherein the deep well of the first region is formed to be in contact with the lower doped layer.

15. The method of claim 11, further comprising:
thermally treating the upper substrate to diffuse dopants in the epitaxial layer into the lower substrate under the epitaxial layer, thereby forming a buried doped layer in the lower substrate.

16. The method of claim 11, further comprising:
forming a deep well in the upper substrate of the second region and/or the third region,
wherein the deep well of the second region and/or the third region and the deep well of the first region are formed simultaneously.

17. The method of claim 11, wherein the at least one well of the second region is formed to be spaced apart from the lower doped layer.

18. The method of claim 11, wherein forming the sidewall doped layers includes:
depositing a spacer insulating layer including dopants of a high concentration on the sidewalls of the trenches; and
thermally treating the spacer insulating layer.

19. The method of claim 11, wherein forming the device isolation patterns includes:
depositing a device isolation insulating layer filling the trenches in which the sidewall doped layers are formed; and
planarizing the device isolation insulating layer until a top surface of the upper substrate is exposed.

20. The method of claim 11, further comprising:
forming a DMOS element in the first region;
forming a CMOS element in the second region; and
forming a bipolar element in the third region.
